(19) United States
(12) Patent Application Publication
(10) Pub. No.: US 2026/0333866 A1
(43) Pub. Date: Oct. 22, 2026

(54) DISPLAY PANEL AND DISPLAY DEVICE

(71) Applicants: NANJING BOE DISPLAY TECHNOLOGY CO., LTD., Nanjing, Jiangsu (CN); BOE TECHNOLOGY GROUP CO., LTD., Beijing (CN); BEIJING BOE TECHNOLOGY DEVELOPMENT CO., LTD., Beijing (CN)

(72) Inventors: Zhilei SUN, Beijing (CN); Baoze FU, Beijing (CN); Haijiao QIAN, Beijing (CN); Qian OUYANG, Beijing (CN)

(73) Assignees: NANJING BOE DISPLAY TECHNOLOGY CO., LTD., Nanjing, Jiangsu (CN); BOE TECHNOLOGY GROUP CO., LTD., Beijing (CN); BEIJING BOE TECHNOLOGY DEVELOPMENT CO., LTD., Beijing (CN)

(21) Appl. No.: 18/852,272

(22) PCT Filed: Nov. 30, 2023
(86) PCT No.: PCT/CN2023/135460

§ 371 Date: Sep. 27, 2024

(51) Int. Cl. H10D 86/40; H10D 86/60

(52) U.S. Cl. CPC H10D 86/441; H10D 86/60

(57) ABSTRACT

A display panel and a display device are provided. The display panel includes display region and peripheral region, first signal lines on a base are provided within peripheral region; the first signal line includes a signal connecting wire part; orthographic projection of cross-line part onto the base partially overlaps with orthographic projection of at least portion of second sub-signal lines onto the base; the cross-line part and the signal connecting wire part included by at least portion of second sub-signal lines are spaced by at least two insulating layers; and/or, the signal connecting wire part includes signal connecting wire portions extending in first direction, the signal connecting wire portion has a width in second direction less than a width threshold; the signal connecting wire part extends in first direction, second direction intersects with first direction. The problem of short-circuit defects of the first signal line is improved.

### TECHNICAL FIELD

The present disclosure relates to the field of display technology, in particular to a display panel and a display device.

### BACKGROUND

In the related technologies, an AD (Abnormal Display) defect and a DGS (Data-Gate Short, a short circuit between a data line and a gate line) defect of a clock signal line refer to a short circuit between a source-drain metal layer and a gate metal layer caused by Cu (copper) diffusion, which subsequently causes a serious defect. In most cases, the diffusion of Cu is considered to be caused by water vapor infiltration that results in generation of Cu+ and Cu2+ ions from Cu corrosion, and then electromigration and thermomigration of Cu occur under the influence of voltage. Other possible causes include foreign matter and ESD (electrostatic discharge), which contribute to the AD of the clock signal line. In the clock signal line region, the voltage difference between a sub-line located in the source-drain metal layer and a bus located in the gate metal layer is relatively large, and an overlapping area between the source-drain metal layer and the gate metal layer is relatively large, so a short circuit often occurs in the clock signal region. An overlap region of the gate metal layer and the source-drain metal layer has a climbing shape, and charge distribution may be uneven due to an uneven structure caused by thin film deformation. Generally, reducing the voltage difference between the bus and the sub-line, or, increasing a thickness of an insulating layer between the gate metal layer and the source-drain metal layer, may have an improvement effect on the defect. However, the above methods may directly affect the MOS (metal-oxide-semiconductor) structure, or cause problems such as film stress mismatch.

### SUMMARY

In an aspect, embodiments of the present disclosure provide a display panel, including a display region and a peripheral region surrounding the display region, where multiple first signal lines located on a base are provided within the peripheral region; each first signal line of the multiple first signal lines includes a signal connecting wire part;
the multiple first signal lines are divided into a first sub-signal line and second sub-signal lines, where the first sub-signal line includes a cross-line part, and each of the second sub-signal lines does not include a cross-line part;
an orthographic projection of the cross-line part onto the base partially overlaps with an orthographic projection of at least a portion of the multiple second sub-signal lines onto the base;
the cross-line part and the signal connecting wire part included by at least a portion of the multiple second sub-signal lines are spaced apart by at least two insulating layers; and/or, the signal connecting wire part included by at least a portion of the multiple second sub-signal lines includes multiple signal connecting wire portions extending in a first direction, each of the multiple signal connecting wire portions has a width in a second direction less than a width threshold; and
the signal connecting wire part extends in the first direction, and the second direction intersects with the first direction.

Optionally, the width threshold is greater than or equal to 5 μm and less than or equal to 8 μm.

Optionally, the display panel includes a first conductive layer, a second conductive layer, and a third conductive layer that are sequentially arranged in a direction away from the base; where at least one insulating layer is provided between adjacent conductive layers; and the cross-line part is located in the third conductive layer, and the signal connecting wire part is located in the first conductive layer.

Optionally, the first conductive layer includes a light shading pattern provided in the display region, the second conductive layer includes a gate line provided in the display region, and the third conductive layer includes a data line provided in the display region.

Optionally, the first signal line further includes a signal body line part;
the signal body line part includes a first body line portion, a second body line portion, and a third body line portion; the first body line portion, the second body line portion, and the third body line portion are located in different conductive layers;
the third body line portion is electrically connected to the second body line portion through a first via hole; and
an orthographic projection of the first body line portion onto the base, an orthographic projection of the second body line portion onto the base, and an orthographic projection of the third body line portion onto the base at least partially overlap.

Optionally, the first signal line further includes a signal lead wire part;
the signal lead wire part is provided between the signal body line part and the signal connecting wire part;
the signal lead wire part includes a first lead wire portion and a second lead wire portion that are located in different conductive layers;
the first lead wire portion is electrically connected to the second lead wire portion through a second via hole; and
an orthographic projection of the first lead wire portion onto the base at least partially overlaps with an orthographic projection of the second lead wire portion onto the base.

Optionally, the signal connecting wire part, the first body line portion, and the first lead wire portion are electrically connected, and the third body line portion and the second lead wire portion are electrically connected.

Optionally, the first signal line further includes a signal body line part;
the signal body line part includes a first body line portion and a second body line portion that are located in different conductive layers;
the first body line portion is electrically connected to the second body line portion through a third via hole; and
an orthographic projection of the first body line portion onto the base and an orthographic projection of the second body line portion onto the base at least partially overlap.

Optionally, the signal connecting wire part is electrically connected to the first body line portion.

Optionally, the orthographic projection of the cross-line part onto the base partially overlaps with an orthographic projection, onto the base, of the signal connecting wire part included by the first signal line to which the cross-line part belongs; and
the cross-line part is electrically connected, through a fourth via hole, to the signal connecting wire part included by the first signal line to which the cross-line part belongs.

Optionally, the display panel further includes a fourth conductive layer arranged on a side of the third conductive layer away from the base;
the first signal line further includes a signal body line part;
the signal body line part includes a first body line portion, a second body line portion, and a third body line portion; the first body line portion, the second body line portion, and the third body line portion are located in different conductive layers;
an orthographic projection of the third body line portion onto the base at least partially overlaps with an orthographic projection of the first body line portion onto the base, and the orthographic projection of the third body line portion onto the base at least partially overlaps with an orthographic projection of the second body line portion onto the base; and
the third body line portion is electrically connected to the second body line portion through a fifth via hole, and the third body line portion is electrically connected to the first body line portion through a sixth via hole.

Optionally, the fourth conductive layer includes a pixel electrode provided in the display region.

Optionally, the first signal line further includes a first transition part; an orthographic projection of the first transition part onto the base at least partially overlaps with an orthographic projection, onto the base, of the signal connecting wire part included by the first signal line to which the cross-line part belongs; the orthographic projection of the first transition part onto the base at least partially overlaps with the orthographic projection of the cross-line part onto the base;

the first transition part is electrically connected to the signal connecting wire part through a seventh via hole, and the first transition part is electrically connected to the cross-line part through an eighth via hole; and
the first transition part and the signal connecting wire are located in different layers, and the first transition part and the cross-line part are located in different conductive layers.

Optionally, the display panel includes a second conductive layer, a third conductive layer, a fifth conductive layer, a sixth conductive layer, and a fourth conductive layer that are sequentially arranged in a direction away from the base; the fifth conductive layer is overlapped and connected with the sixth conductive layer; at least one insulating layer is provided between the second conductive layer and the third conductive layer, at least one insulating layer is provided between the third conductive layer and the fifth conductive layer, and at least one insulating layer is provided between the sixth conductive layer and the fourth conductive layer; and
at least a portion of the cross-line part is located in the sixth conductive layer, and the signal connecting wire part is located in the second conductive layer.

Optionally, the second conductive layer includes a gate line provided in the display region, the third conductive layer includes a data line provided in the display region, the fifth conductive layer includes a common electrode provided in the display region, and the sixth conductive layer includes an auxiliary metal pattern provided in the display region.

Optionally, the first signal line further includes a first transition part;
the first transition part is electrically connected to the signal connecting wire part through a ninth via hole, and the first transition part is electrically connected to the cross-line part through a tenth via hole; and
the first transition part and the signal connecting wire part are located in different layers, and the first transition part and the cross-line part are located in different conductive layers.

Optionally, the first signal line further includes a first transition part and a second transition part; the second transition part is overlapped and connected with the cross-line part;
the first transition part is electrically connected to the signal connecting wire part through a thirteenth via hole, and the first transition part is electrically connected to the second transition part through a fourteenth via hole; and
the first transition part and the signal connecting wire part are located in different layers, and the first transition part and the second transition part are located in different conductive layers.

Optionally, the first signal line further includes a third transition part and a connecting wire;
the third transition part is electrically connected to the cross-line part through an eleventh via hole, and the third transition part is electrically connected to the connecting wire through a twelfth via hole; and
the third transition part and the cross-line part are located in different conductive layers, and the third transition part and the connecting wire are located in different conductive layers.

Optionally, the first signal line further includes a first connecting part located in the fifth conductive layer; the first connecting part is overlapped and connected with the cross-line part;
an orthographic projection of the first connecting part onto the base covers an orthographic projection of a cross-line region onto the base; and
the cross-line region is an overlap region between the cross-line part and the signal connecting wire part included by at least a portion of the multiple second sub-signal lines.

Optionally, the cross-line part includes a first cross-line portion and a second cross-line portion;
an orthographic projection of the first cross-line portion onto the base covers an orthographic projection of the second cross-line portion onto the base; and
the first cross-line portion is directly overlapped and connected with the second cross-line portion.

Optionally, the first signal line further includes a first transition part and a second transition part; the second transition part is electrically connected to the first cross-line portion;
the first transition part is electrically connected to a clock signal connecting wire part through a thirteenth via hole, and the first transition part is electrically connected to the second transition part through a fourteenth via hole; and
the first transition part and the signal connecting wire part are located in different conductive layers, and the first transition part and the second transition part are located in different conductive layers.

Optionally, the first signal line further includes a third transition part, a fourth transition part, and a connecting wire;
the fourth transition part is electrically connected to the first cross-line portion; the fourth transition part and the first cross-line portion are located in a same conductive layer;
the third transition part is electrically connected to the fourth transition part through a fifteenth via hole, and the third transition part is electrically connected to the connecting wire through a sixteenth via hole; and
the third transition part and the fourth transition part are located in different conductive layers, and the third transition part and the connecting wire are located in different conductive layers.

In a second aspect, embodiments of the present disclosure provide a display device, including the display panel as described above.

### BRIEF DESCRIPTION OF THE DRAWINGS

FIG. 1 is a plan layout view of first signal lines in a display panel according to at least one embodiment of the present disclosure;

FIG. 2 is a plan layout view of a light shading metal layer of FIG. 1;

FIG. 3 is a plan layout view of a gate metal layer of FIG. 1;

FIG. 4 is a plan layout view of a source-drain metal layer of FIG. 1;

FIG. 5 is a cross-sectional view taken along line A-A′ in FIG. 4;

FIG. 6 is a cross-sectional view taken along line B-B′ in FIG. 4;

FIG. 7A is a cross-sectional view taken along line C-C′ in FIG. 4;

FIG. 7B is a schematic view of elements in a peripheral region ZY and a display region AA of a display panel;

FIG. 7C is a cross-sectional view taken along line K-K′ in FIG. 7B;

FIG. 8 shows a pattern obtained after a light shading metal layer is formed as a film and then etched in fabricating of the first signal lines in at least one embodiment shown in FIGS. 1 to 7A;

FIG. 9 shows a pattern obtained after a buffer layer is formed as a film, a gate insulating layer is formed as a film, a gate metal layer is formed as a film and then etched, and the gate insulating layer is etched using the gate metal layer as a mask, in fabricating of the first signal lines in at least one embodiment shown in FIGS. 1 to 7A;

FIG. 10 is a schematic view of making connection holes for a light shading metal layer, a gate metal layer, and a source-drain metal layer after an interlayer dielectric layer is formed as a film, in fabricating of the first signal lines in at least one embodiment shown in FIGS. 1 to 7A;

FIG. 11 shows a pattern obtained after the source-drain metal layer is formed as a film and then etched in fabricating of the first signal lines in at least one embodiment shown in FIGS. 1 to 7A;

FIG. 12A, FIG. 12B, FIG. 12C, FIG. 12D, FIG. 12E, FIG. 12F, and FIG. 12G are cross-sectional views of the above steps;

FIG. 13 is a plan layout view of first signal lines in a display panel according to at least one embodiment of the present disclosure;

FIG. 14 is a plan layout view of a light shading metal layer of FIG. 13;

FIG. 15 is a plan layout view of a source-drain metal layer of FIG. 13;

FIG. 16 is a cross-sectional view taken along line D-D′ in FIG. 13;

FIG. 17 is a layout view of first signal lines in a display panel according to at least one embodiment of the present disclosure;

FIG. 18 is a plan layout view of a light shading metal layer of FIG. 17;

FIG. 19 is a plan layout view of a source-drain metal layer of FIG. 17;

FIG. 20 is a plan layout view of a pixel electrode layer of FIG. 17;

FIG. 21 is a cross-sectional view taken along line E-E′ in FIG. 17;

FIG. 22 is a plan layout view of first signal lines in a display panel according to at least one embodiment of the present disclosure;

FIG. 23 is a plan layout view of a gate metal layer of FIG. 22;

FIG. 24 is a plan layout view of a source-drain metal layer of FIG. 22;

FIG. 25 is a plan layout view of first signal lines in a display panel according to at least one embodiment of the present disclosure;

FIG. 26 is a plan layout view of a gate metal layer of FIG. 25;

FIG. 27 is a plan layout view of a source metal layer of FIG. 25;

FIG. 28 is a plan layout view of a metal auxiliary layer of FIG. 25;

FIG. 29A is a plan layout view of a pixel electrode layer of FIG. 25;

FIG. 29B is a schematic view of elements in a peripheral region ZY and a display region AA of a display panel;

FIG. 29C is a cross-sectional view taken along line L-L′ in FIG. 29B;

FIG. 30 is a cross-sectional view taken along line F-F′ in FIG. 25;

FIG. 31 is a cross-sectional view taken along line G-G′ in FIG. 25;

FIG. 32 is a cross-sectional view taken along line H-H′ in FIG. 25;

FIGS. 33 and 34 are plan layout views of first signal lines in a display panel according to at least one embodiment of the present disclosure;

FIG. 35 is a cross-sectional view taken along line I-I′ in FIG. 33;

FIG. 36 is a plan layout view of first signal lines in a display panel according to at least one embodiment of the present disclosure;

FIG. 37 is a plan layout view of a gate metal layer of FIG. 36;

FIG. 38 is a plan layout view of a source-drain metal layer of FIG. 36;

FIG. 39 is a plan layout view of a common electrode layer of FIG. 36;

FIG. 40 is a plan layout view of a metal auxiliary layer of FIG. 36;

FIG. 41 is a plan layout view of a pixel electrode layer of FIG. 36;

FIG. 42 is a cross-sectional view taken along line J-J′ in FIG. 36;

FIG. 43 is a plan layout view of first signal lines in a display panel according to at least one embodiment of the present disclosure;

FIG. 44 is a plan layout view of a gate metal layer of FIG. 43;

FIG. 45 is a plan layout view of a source-drain metal layer of FIG. 43;

FIG. 46 is a plan layout view of a common electrode layer of FIG. 43;

FIG. 47 is a plan layout view of a metal auxiliary layer of FIG. 43;

FIG. 48 is a plan layout view of a pixel electrode layer of FIG. 43;

FIG. 49 shows a pattern obtained after a gate metal layer is formed as a film in fabricating of the first signal lines shown in FIG. 33;

FIG. 50 shows a pattern obtained after a gate insulating layer is formed as a film, a semiconductor layer is formed as a film and then etched, and a source-drain metal layer is formed as a film and then etched, in fabricating of the first signal lines shown in FIG. 33;

FIG. 51 shows a pattern obtained after a first passivation layer is formed as a film, an organic layer is coated, exposed and developed, and a common electrode layer is formed as a film and then etched, in fabricating of the first signal lines shown in FIG. 33;

FIG. 52 shows a pattern obtained after a metal auxiliary layer is formed as a film and then etched in fabricating of the first signal lines shown in FIG. 33;

FIG. 53 is a schematic view of reserving connection hole regions for the metal auxiliary layer, the gate metal layer, and the source-drain metal layer in fabricating of the first signal lines shown in FIG. 33;

FIG. 54 shows a pattern obtained after a pixel electrode layer is formed as a film and then etched in fabricating of the first signal lines shown in FIG. 33;

FIG. 55 shows a pattern obtained after a gate metal layer is formed as a film and then etched in fabricating of the first signal lines shown in FIG. 43;

FIG. 56 shows a pattern obtained after a gate insulating layer is formed as a film, a semiconductor layer is formed as a film and then etched, and a source-drain metal layer is formed as a film and then etched, in fabricating of the first signal lines shown in FIG. 43;

FIG. 57 shows a pattern obtained after a first passivation layer is formed as a film, an organic layer is coated, exposed and developed, and a common electrode layer is formed as a film and then etched, in fabricating of the first signal lines shown in FIG. 43;

FIG. 58 shows a pattern obtained after a metal auxiliary layer is formed as a film and then etched in fabricating of the first signal lines shown in FIG. 43;

FIG. 59 is a schematic view of reserving connection hole regions in the common electrode layer, the gate metal layer, and the source-drain metal layer in fabricating of the first signal lines shown in FIG. 43; and

FIG. 60 shows a pattern obtained after a pixel electrode layer is formed as a film and then etched in fabricating of the first signal lines shown in FIG. 43.

### DETAILED DESCRIPTION

The technical solutions in the embodiments of the present disclosure will be clearly and completely described below in conjunction with the drawings in the embodiments of the present disclosure. Apparently, the embodiments described are merely a part of rather than all embodiments of the present disclosure. Based on the embodiments of the present disclosure, all other embodiments obtained by a person of ordinary skill in the art without any creative efforts are within the protection scope of the present disclosure.

The transistors used in all embodiments of the present disclosure may be thin film transistors or field effect transistors or other devices having the same characteristics. In embodiments of the present disclosure, to distinguish between two electrodes of a transistor other than a gate electrode, one of the electrodes is referred to as a first electrode and the other is referred to as a second electrode.

In practical operation, when the transistor is a thin film transistor or a field effect transistor, the first electrode may be a drain electrode, and the second electrode may be a source electrode; or, the first electrode may be a source electrode, and the second electrode may be a drain electrode.

A display panel according to embodiments of the present disclosure includes a display region and a peripheral region surrounding the display region, where multiple first signal lines located on a base are provided within the peripheral region; each first signal line of the multiple first signal lines includes a signal connecting wire part;
the multiple first signal lines are divided into multiple first sub-signal lines and multiple second sub-signal lines, where each of the multiple first sub-signal lines includes a cross-line part, and each of the multiple second sub-signal lines does not include a cross-line part;
an orthographic projection of the cross-line part onto the base partially overlaps with an orthographic projection, onto the base, of the signal connecting wire part included by at least a portion of the multiple second sub-signal lines;
the cross-line part and at least a portion of the multiple second sub-signal lines are spaced apart by at least two insulating layers; and/or, the signal connecting wire part includes multiple signal connecting wire portions extending in a first direction, each of the multiple signal connecting wire portions has a width in a second direction less than a width threshold; and
the signal connecting wire part extends in the first direction, and the second direction intersects with the first direction.

Optionally, the first direction may be a vertical direction, and the second direction may be a horizontal direction. Or, the first direction may be a horizontal direction, and the second direction may be a vertical direction. And the present disclosure is not limited thereto.

In each of the plan layout views of the present disclosure, an X-Y coordinate system is drawn, where the Y direction may be a first direction, and the X direction may be a second direction. For example, the X direction may be a horizontal direction, and the Y direction may be a vertical direction.

In at least one embodiment of the present disclosure, the cross-line part and the signal connecting wire part included by at least a portion of the multiple second sub-signal lines are set to be spaced apart by at least two insulating layers; and/or, the signal connecting wire part is set to include multiple signal connecting wire portions extending in a first direction, and each of the multiple signal connecting wire portions is set to have a width in a second direction less than a width threshold. In this way, the short-circuit defect of the first signal line is improved without affecting the MOS structure or causing problems such as film stress mismatch.

In at least one embodiment of the present disclosure, the width threshold is greater than or equal to 5 μm and less than or equal to 8 μm.

In a particular implementation, the width threshold may be greater than or equal to 5 μm and less than or equal to 8 μm, for example, the width threshold may be 6 μm. And the present disclosure is not limited thereto.

In at least one embodiment of the present disclosure, the first signal lines may be divided into two types:
the first class is a first sub-signal line including a cross-line part; and
the second class is a second sub-signal line not including a cross-line part.

Optionally, the first signal line may be, but is not limited to, a clock signal line.

In a particular implementation, the first signal line may be other types of signal lines, and at least one embodiment of the present disclosure may be applicable to other scenarios of via hole connection in a display panel.

Optionally, the display panel includes a first conductive layer, a second conductive layer, and a third conductive layer that are sequentially arranged in a direction away from the base; at least one insulating layer is provided between adjacent conductive layers; and
the cross-line part is located in the third conductive layer, and the signal connecting wire part is located in the first conductive layer.

In at least one embodiment of the present disclosure, the first conductive layer may be a light shading metal layer, the second conductive layer may be a gate metal layer, and the third conductive layer may be a source-drain metal layer;
a buffer layer and a gate insulating layer may be provided between the light shading metal layer and the gate metal layer, the buffer layer is provided between the gate insulating layer and the light shading metal layer, and an interlayer dielectric layer may be provided between the gate metal layer and the source-drain metal layer;
the cross-line part may be located in the third conductive layer, the signal connecting wire may be located in the first conductive layer, and the buffer layer and the interlayer dielectric layer may be provided between the cross-line part and the signal connecting wire.

In at least one embodiment of the present disclosure, the first conductive layer may include a light shading pattern provided in the display region, the second conductive layer may include a gate line provided in the display region, and the third conductive layer may include a data line provided in the display region.

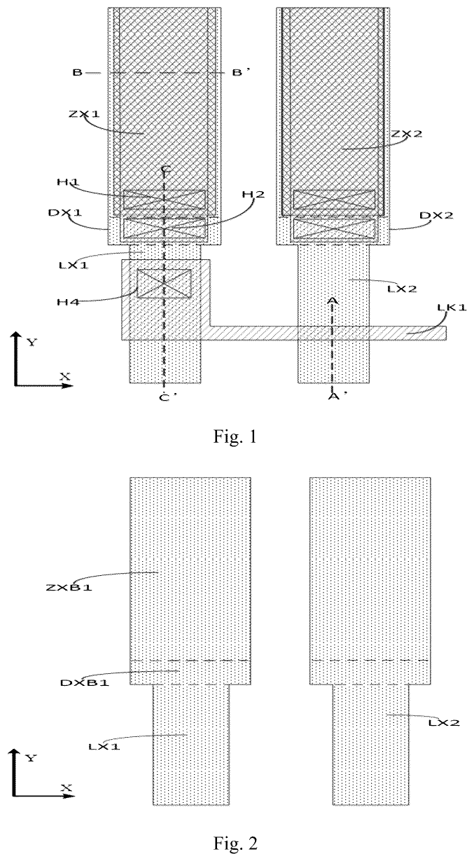

As shown in FIG. 1, a first one of the first signal lines includes a cross-line part LK1 and a first signal connecting wire part LX1; and
a second one of the first signal lines includes a second signal connecting wire part LX2.

An orthographic projection of the cross-line part LK1 onto the base partially overlaps with an orthographic projection of the second signal connecting wire part LX2 onto the base.

The cross-line part LK1 is formed in a source-drain metal layer, and the first signal connecting wire part LX1 and the second signal connecting wire part LX2 are formed in a light shading metal layer.

The first signal connecting wire part LX1 and the second signal connecting wire part LX2 extend in the vertical direction.

In a particular implementation, the first signal lines may be provided at the peripheral region of the display panel, for example, the first signal lines may be provided at a left side edge and/or a right side edge of the display region of the display panel, and the first signal line mays extend in the vertical direction, but not limited thereto.

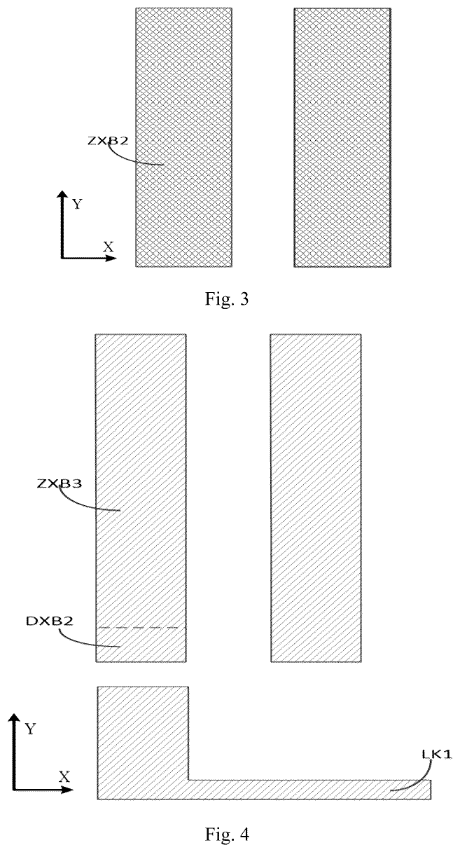

FIG. 1 is a plan layout view of two first signal lines in a display panel according to at least one embodiment, FIG. 2 is a plan layout view of a light shading metal layer of FIG. 1, FIG. 3 is a plan layout view of a gate metal layer of FIG. 1, and FIG. 4 is a plan layout view of a source-drain metal layer of FIG. 1.

In at least one embodiment of the present disclosure, the first signal line further includes a signal body line part;
the signal body line part includes a first body line portion, a second body line portion, and a third body line portion; the first body line portion, the second body line portion, and the third body line portion are located in different conductive layers;
the third body line portion is electrically connected to the second body line portion through a first via hole; and
an orthographic projection of the first body line portion onto the base, an orthographic projection of the second body line portion onto the base, and an orthographic projection of the third body line portion onto the base at least partially overlap.

In a particular implementation, the first signal line may further include a signal body line part;
the signal body line part may include a first body line portion, a second body line portion, and a third body line portion, the first body line portion may be located in a first conductive layer, the second body line portion may be located in a second conductive layer, and the third body line portion may be located in a third conductive layer; the third body line portion may be electrically connected to the second body line portion through a first via hole.

As shown in FIGS. 1 to 4, the first one of the first signal lines further includes a first signal body line part ZX1, and the second one of the first signal lines further includes a second signal body line part ZX2.

The first signal body line part may include a first body line portion ZXB1, a second body line portion ZXB2, and a third body line portion ZXB3.

The ZXB1 is located in the light shading metal layer, the ZXB2 is located in the gate metal layer, and the ZXB3 is located in the source-drain metal layer.

The third body line portion ZXB3 is electrically connected to the second body line portion ZXB2 through a first via hole H1.

In at least one embodiment of the present disclosure, the first signal line further includes a signal lead wire part;
the signal lead wire part is provided between the signal body line part and the signal connecting wire part;
the signal lead wire part includes a first lead wire portion and a second lead wire portion that are located in different conductive layers;
the first lead wire portion is electrically connected to the second lead wire portion through a second via hole; and
an orthographic projection of the first lead wire portion onto the base at least partially overlaps with an orthographic projection of the second lead wire portion onto the base.

In a particular implementation, the first signal line may further include a signal lead wire part. The signal lead wire part may be provided between the signal body line part and the signal connecting wire part. The signal lead wire part may include a first lead wire portion and a second lead wire portion, the first lead wire portion may be located in the first conductive layer, and the second lead wire portion may be located in a third conductive layer. The first lead wire portion may be electrically connected to the second lead wire portion through a second via hole.

In at least one embodiment of the present disclosure, the signal connecting wire part, the first body line portion, and the first lead wire portion are electrically connected, and the third body line portion and the second lead wire portion are electrically connected.

In a particular implementation, the signal connecting wire part, the first body line portion, and the first lead wire portion may be electrically connected to each other, and the third body line portion and the second lead wire portion may be electrically connected to each other.

As shown in FIGS. 1 to 4, the first one of the first signal lines may include a first signal lead wire part DX1, and the second one of the first signal lines may include a second signal lead wire part DX2.

DX1 is provided between ZX1 and LX1.

The first signal lead wire part DX1 includes a first lead wire portion DXB1 and a second lead wire portion DXB2. The DXB1 may be located in the light shading metal layer, and the DXB2 may be located in the source-drain metal layer. The DXB1 may be electrically connected to the DXB2 through a second via hole H2.

An orthographic projection of the first lead wire portion DXB1 onto the base at least partially overlaps with an orthographic projection of the second lead wire portion DXB2 onto the base.

The signal connecting wire part LX1, the first body line portion ZXB1, and the first lead wire portion DXB1 are electrically connected, and the third body line portion ZXB3 and the second lead wire portion DXB2 are electrically connected.

In at least one embodiment of the present disclosure, the orthographic projection of the cross-line part onto the base partially overlaps with an orthographic projection, onto the base, of the signal connecting wire part included by the first signal line to which the cross-line part belongs; and
the cross-line part is electrically connected, through a fourth via hole, to the signal connecting wire part included by the first signal line to which the cross-line part belongs.

As shown in FIGS. 1 to 4, an orthographic projection of the cross-line part LK1 onto the base partially overlaps with an orthographic projection of the first signal connecting wire part LX1 onto the base.

The cross-line part LK1 is electrically connected to the first signal connecting wire part LX1 through a fourth via hole H4.

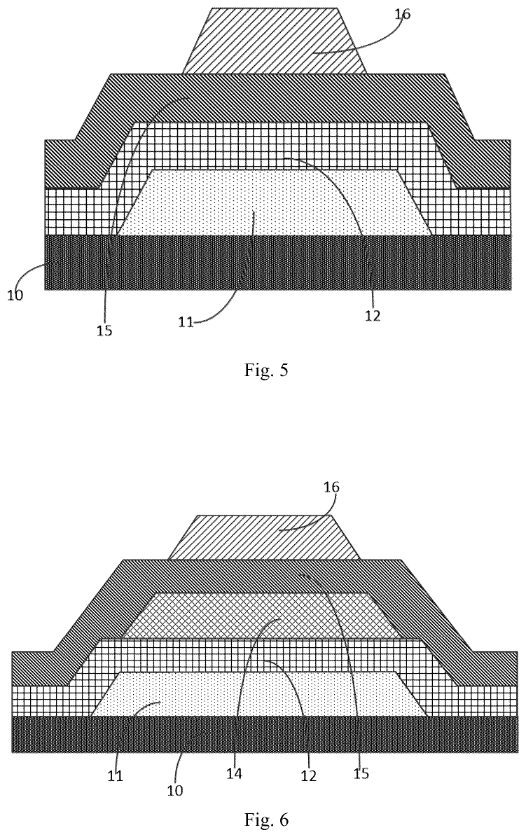

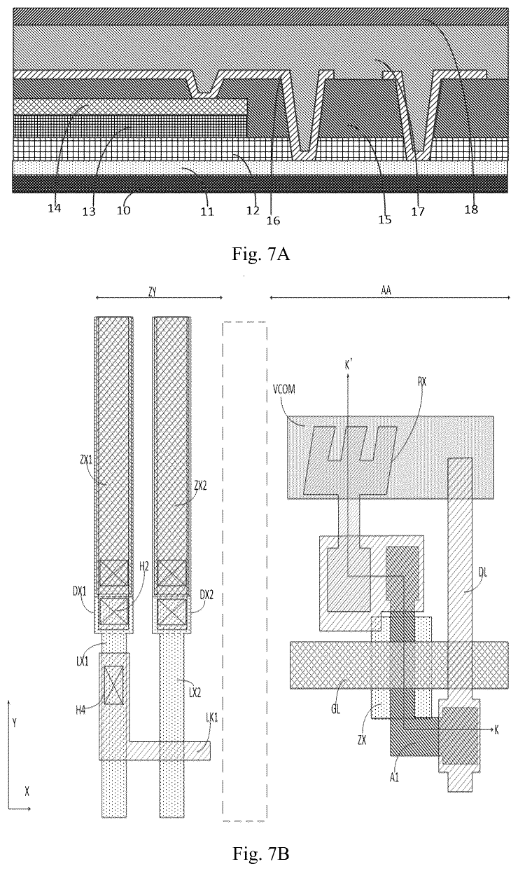

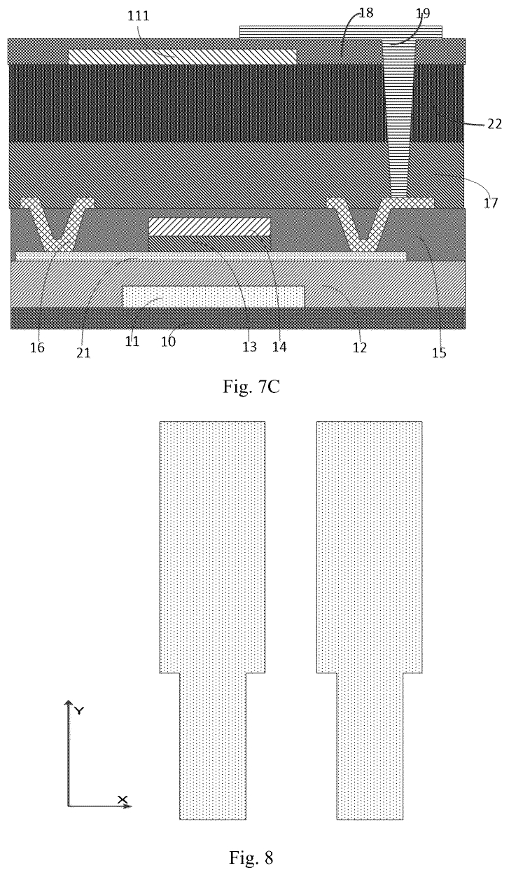

FIG. 5 is a cross-sectional view taken along line A-A′ in FIG. 4, FIG. 6 is a cross-sectional view taken along line B-B′ in FIG. 4, and FIG. 7A is a cross-sectional view taken along line C-C′ in FIG. 4.

In FIGS. 5 to 7A, reference numeral 10 denotes a base, reference numeral 11 denotes a light shading metal layer, reference numeral 12 denotes a buffer layer, reference numeral 13 denotes a gate insulating layer, reference numeral 14 denotes a gate metal layer, reference numeral 15 denotes an interlayer dielectric layer, reference numeral 16 denotes a source-drain metal layer, reference numeral 17 denotes a first passivation layer, and reference numeral 18 denotes a second passivation layer.

In at least one embodiment shown in FIGS. 1 to 7A, the cross-line part LK1 crosses over the second one of the first signal lines so as to be led to a GOA (Gate On Array, a gate driving circuit provided on an array base) region. For an original etching process of an interlayer dielectric layer, the etching time is appropriately increased to ensure that the buffer layer is etched away together with the interlayer dielectric layer, in this way, a source-drain metal layer is directly connected to a light shading metal layer when the source-drain metal layer is formed as a film, to achieve signal transmission.

In at least one embodiment shown in FIGS. 1 to 7A, a distance between the first one of the first signal lines and the second one of the first signal lines is about 7 μm, a width, in the horizontal direction, of the first body line portion ZXB1 may be about 17 μm, a width, in the horizontal direction, of the second body line portion ZXB2 may be about 14.6 μm, and a width, in the horizontal direction, of the third body line portion ZXB3 may be about 11.2 μm. Based on the impedance reduction of the signal body line part having the three-layer structure, the width, in the horizontal direction, of each body line portion may be appropriately reduced so as to reduce the width of the frame. For example, the width of each body line portion in the horizontal direction may be reduced by about 3.5 μm as compared with the related technologies, which is advantageous to reduce the width of the frame to some extent.

In at least one embodiment shown in FIGS. 1 to 7A, the insulating layers between the cross-line part LK1 and the first signal connecting wire part LX1 are a buffer layer and an interlayer dielectric layer, and the total thickness of the insulating layers between LK1 and LX1 is about 8000 Å. As compared with the related technologies, the total thickness of the insulating layers is doubled, which may effectively improve the AD problem of the first signal line. In addition, with the three-layer metal structure of the first signal line, the resistance of the first signal line may be reduced and the signal load may be reduced.

In at least one embodiment shown in FIGS. 1 to 7A, despite the increased climbing height of the source-drain metal layer, the Taper angle may be controlled by process parameters, preventing the breakage of the source-drain metal layer during climbing. In a particular implementation, a thickness of the buffer layer, a thickness of the first passivation layer, and a thickness of the second passivation layer may be 4500 Å, 3000 Å and 2000 Å, respectively, and a thickness of the source-drain metal layer is between 3300 Å and 3500 Å, so that the problem of the breakage of the source-drain metal layer during climbing may not occur.

When at least one embodiment shown in FIGS. 1 to 7A is adopted, the thickness of a left side frame and a right side frame of the display panel is changed, and the increased thickness is the thickness of the light shading metal layer, where the thickness is 3300 Å. Therefore, in order to ensure that the overall cell thickness of the display panel is consistent, the light shading metal layer may be added to both an upper side frame and a lower side frame of the display panel; and at the upper side frame and the lower side frame of the display panel, the original single-layer wiring may be changed to double-layer wiring, and the original double-layer wiring may be changed to three-layer wiring, or, a dummy three-layer structure is made on the frame sealing regions of a terminal side and a bottom side (the dummy three-layer structure includes a conductive pattern formed in the light shading metal layer, a conductive pattern formed in the gate metal layer, and a conductive pattern formed in the source-drain metal layers), so as to ensure the overall cell thickness.

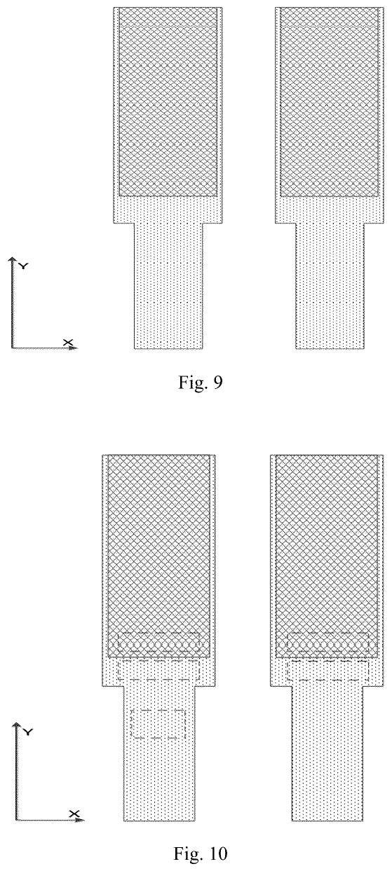

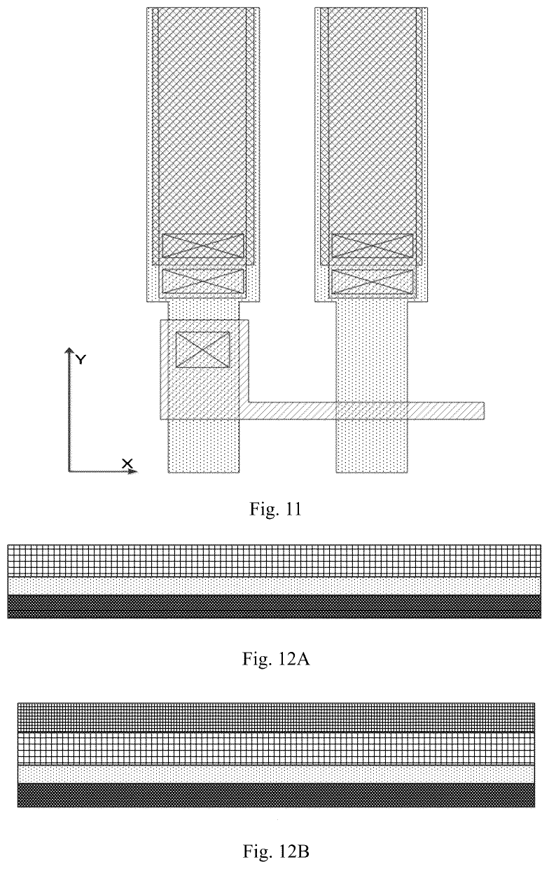

In fabricating the first signal lines in at least one embodiment shown in FIGS. 1 to 7A, a specific improved process is as follows:
1, a light shading metal layer is formed as a film and etched, to obtain the pattern shown in FIG. 8;
2, a buffer layer is formed as a film, a gate insulating layer is formed as a film, a gate metal layer is formed as a film and etched, and the gate insulating layer is etched using the gate metal layer as a mask, to obtain the pattern shown in FIG. 9;
3, an interlayer dielectric layer is formed as a film, and an etching time for making holes is increased at the positions shown in FIG. 10, to make connection holes for the light shading metal layer, the gate metal layer, and the source-drain metal layer; and
4, the source-drain metal layer is formed as a film and etched, to obtain the pattern shown in FIG. 11.

The subsequent steps include forming a first passivation layer as a film and forming a second passivation layer as a film, which are not different from those in the process in the related technologies.

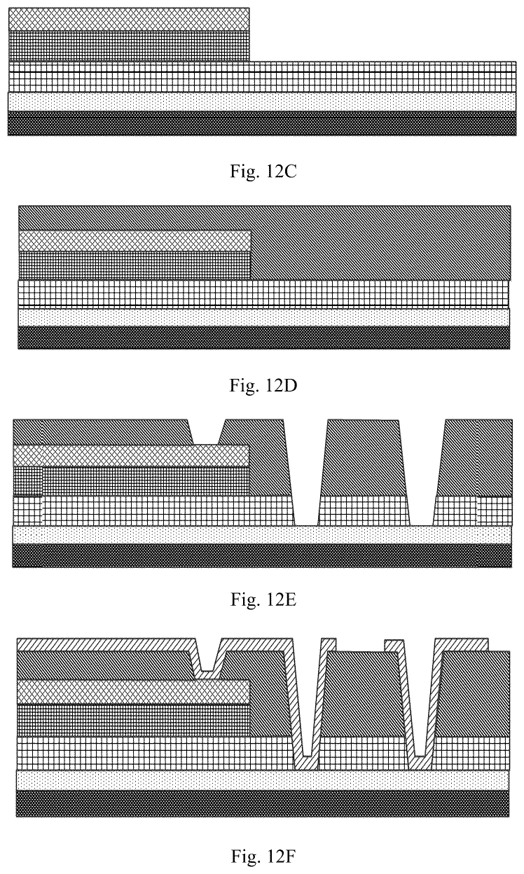

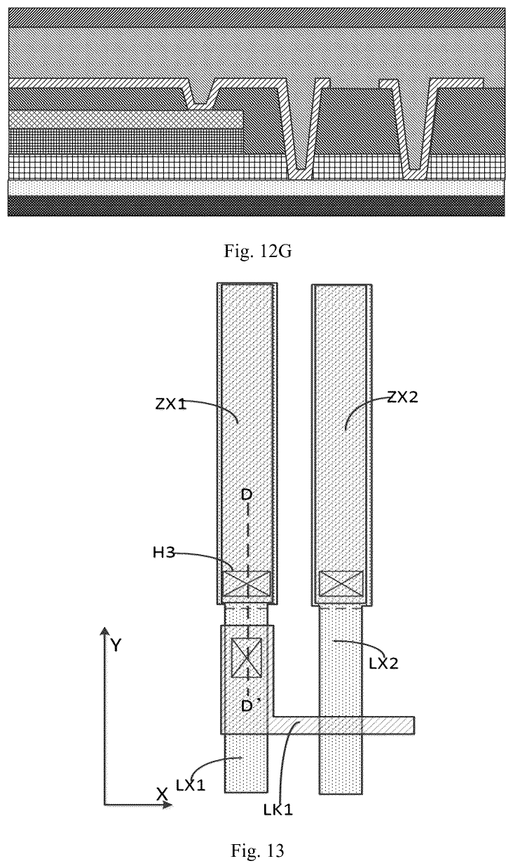

Cross-sectional views of the above steps are shown in FIG. 12A, FIG. 12B, FIG. 12C, FIG. 12D, FIG. 12E, FIG. 12F, and FIG. 12G.

As shown in FIG. 12A, on the base 10, a light shading metal layer is formed as a film and etched, and a buffer layer is formed as a film.

As shown in FIG. 12B, a gate insulating layer is formed as a film and a gate metal layer is formed as a film.

As shown in FIG. 12C, the gate metal layer is etched, and the gate insulating layer is etched using the gate metal layer as a mask.

As shown in FIG. 12D, an interlayer dielectric layer is formed as a film.

As shown in FIG. 12E, the interlayer dielectric layer is etched.

As shown in FIG. 12F, a source-drain metal layer is formed as a film and etched.

As shown in FIG. 12G, a first passivation layer is formed as a film and a second passivation layer is formed as a film.

As shown in FIG. 7B, two first signal lines shown in FIG. 1 are provided in a peripheral region ZY, and a gate line GL, a data line DL and a transistor in a sub-pixel are provided in a display region AA.

In FIG. 7B, reference sign ZX denotes a light shading pattern, reference sign A1 denotes an active pattern of the transistor, reference sign VCOM denotes a common electrode, and reference sign PX denotes a pixel electrode.

In at least one embodiment corresponding to FIG. 7B, the light shading pattern ZX is located in the light shading metal layer, the active pattern Al of the transistor is located in the semiconductor layer, the pixel electrode PX is located in the pixel electrode layer, the common electrode VCOM is located in the common electrode layer, the gate line GL is located in the gate metal layer, and the data line DL is located in the source-drain metal layer.

FIG. 7C is a cross-sectional view taken along line K-K′ in FIG. 7B.

In FIG. 7C, reference numeral 10 denotes a base, reference numeral 11 denotes a light shading metal layer, reference numeral 12 denotes a buffer layer, reference numeral 21 denotes a semiconductor layer, reference numeral 13 denotes a gate insulating layer, reference numeral 14 denotes a gate metal layer, reference numeral 15 denotes an interlayer dielectric layer, reference numeral 16 denotes a source-drain metal layer, reference numeral 17 denotes a first passivation layer, reference numeral 22 denotes an organic layer, reference numeral 111 denotes a common electrode layer, reference numeral 18 denotes a second passivation layer, and reference numeral 19 denotes a pixel electrode layer. In the related technologies, the dry etching of the gate insulating layer across the whole surface of the large glass plate may result in a poor Taper angle of or even over-etching of the gate insulating layer, thereby causing the breakage of the subsequent interlayer dielectric layer, and causing the source-drain metal layer to penetrate into the breakage position of the interlayer dielectric layer during forming of the source-drain metal layer as a film, as a result, the local distance between the source-drain metal layer and the gate metal layer is shortened. Consequently, the capacitor structure of the source-drain metal layer-interlayer dielectric layer-gate metal layer becomes susceptible to breakdown, increasing the probability of Cu interconnection. In order to avoid the problems of poor taper angle of the gate insulating layer and over-etching of the gate insulating layer that are caused by dry etching of the gate insulating layer, in at least one embodiment of the present disclosure, the first signal line may employ a double-layer metal structure, and the signal body line part may be set to include a first body line portion and a second body line portion, the first body line portion may be located in the first conductive layer, and the second body line portion may be located in the third conductive layer.

In at least one embodiment of the present disclosure, the first signal line further includes a signal body line part;
the signal body line part includes a first body line portion and a second body line portion that are located in different conductive layers;
the first body line portion is electrically connected to the second body line portion through a third via hole; and
an orthographic projection of the first body line portion onto the base and an orthographic projection of the second body line portion onto the base at least partially overlap.

In a particular implementation, the first signal line may include a signal body line part, and the signal body line part may include a first body line portion and a second body line portion.

Optionally, the first body line portion is located in the first conductive layer, and the second body line portion forms the third conductive layer.

In at least one embodiment of the present disclosure, the signal connecting wire part is electrically connected to the first body line portion.

As shown in FIG. 13, the first one of the first signal lines includes a cross-line part LK1 and a first signal connecting wire part LX1; and
the second one of the first signal lines includes a second signal connecting wire part LX2.

An orthographic projection of the cross-line part LK1 onto the base partially overlaps with an orthographic projection of the second signal connecting wire part LX2 onto the base.

The cross-line part LK1 is formed in a source-drain metal layer, and the first signal connecting wire part LX1 and the second signal connecting wire part LX2 are formed in a light shading metal layer.

The first signal connecting wire part LX1 and the second signal connecting wire part LX2 extend in the vertical direction.

In a particular implementation, the first signal lines may be provided in the peripheral region of the display panel, for example, the first signal lines may be provided at a left side edge and/or a right side edge of the display region of the display panel, and the first signal line may extend in the vertical direction, which is not limited thereto.

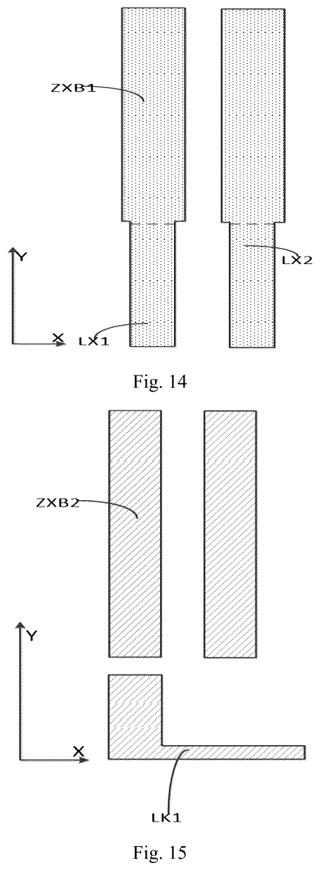

FIG. 13 is a plan layout view of two first signal lines in a display panel according to at least one embodiment, FIG. 14 is a plan layout view of the light shading metal layer of FIG. 13, and FIG. 15 is a plan layout view of the source-drain metal layer of FIG. 13.

As shown in FIGS. 13 to 15, the first one of the first signal lines further includes a first signal body line part ZX1, and the second one of the first signal lines further includes a second signal body line part ZX2.

The first signal body line part may include a first body line portion ZXB1 and a second body line portion ZXB2.

The ZXB1 is located in the light shading metal layer, and the ZXB2 is located in the source-drain metal layer.

The first body line portion ZXB1 is electrically connected to the second body line portion ZXB2 through a third via hole H3.

An orthographic projection of the first body line portion ZXB1 onto the base and an orthographic projection of the second body line portion ZXB2 onto the base at least partially overlap.

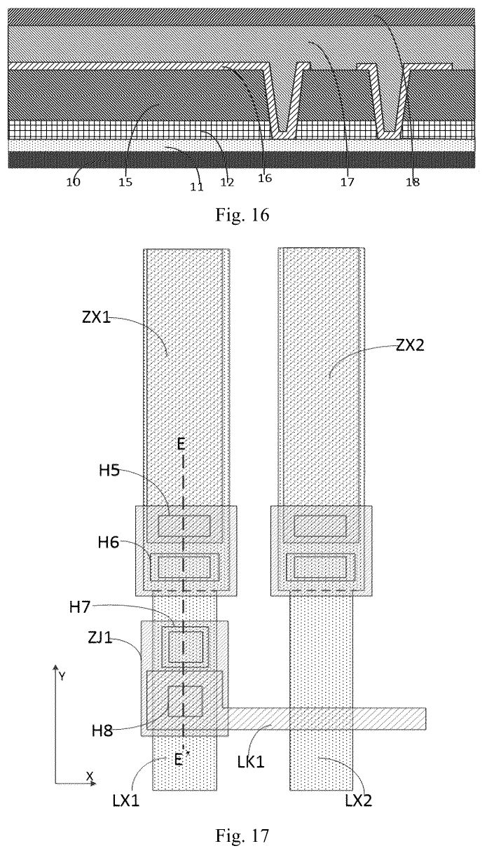

FIG. 16 is a cross-sectional view taken along line D-D′ in FIG. 13.

In FIG. 16, reference numeral 10 denotes a base, reference numeral 11 denotes a light shading metal layer, reference numeral 12 denotes a buffer layer, reference numeral 15 denotes an interlayer dielectric layer, reference numeral 16 denotes a source-drain metal layer, reference numeral 17 denotes a first passivation layer, and reference numeral 18 denotes a second passivation layer.

In a particular implementation, in addition to the solution where the source-drain metal layer is directly connected to the light shading metal layer, a solution where the pixel electrode layer is overlapped and connected with the source-drain metal layer and the light shading metal layer may be used.

In at least one embodiment of the present disclosure, the display panel further includes a fourth conductive layer arranged on a side of the third conductive layer away from the base;
the first signal line further includes a signal body line part;
the signal body line part includes a first body line portion, a second body line portion, and a third body line portion; the first body line portion, the second body line portion, and the third body line portion are located in different conductive layers;
an orthographic projection of the third body line portion onto the base at least partially overlaps with an orthographic projection of the first body line portion onto the base, and the orthographic projection of the third body line portion onto the base at least partially overlaps with an orthographic projection of the second body line portion onto the base; and
the third body line portion is electrically connected to the second body line portion through a fifth via hole, and the third body line portion is electrically connected to the first body line portion through a sixth via hole.

In at least one embodiment of the present disclosure, the fourth conductive layer may include a pixel electrode provided in the display region.

Optionally, the first body line portion is located in the first conductive layer, the second body line portion forms the third conductive layer, and the third body line portion is located in the fourth conductive layer.

In at least one embodiment of the present disclosure, the fourth conductive layer may be a pixel electrode layer, the pixel electrode layer may be made of, for example, ITO (indium tin oxide), and the pixel electrode layer may be provided on a side of the second passivation layer away from the source-drain metal layer.

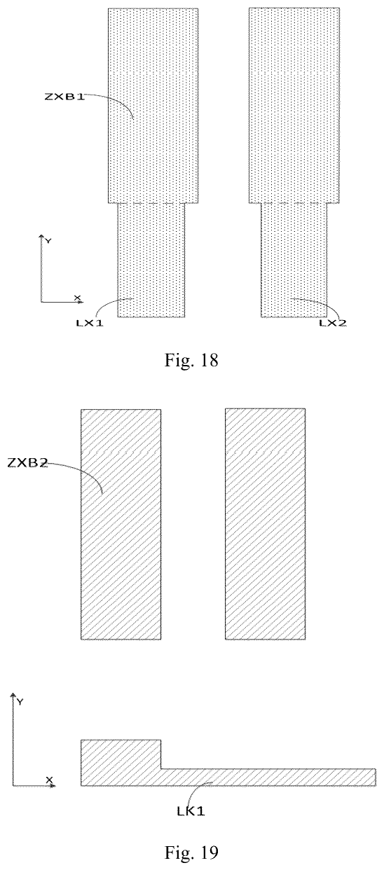

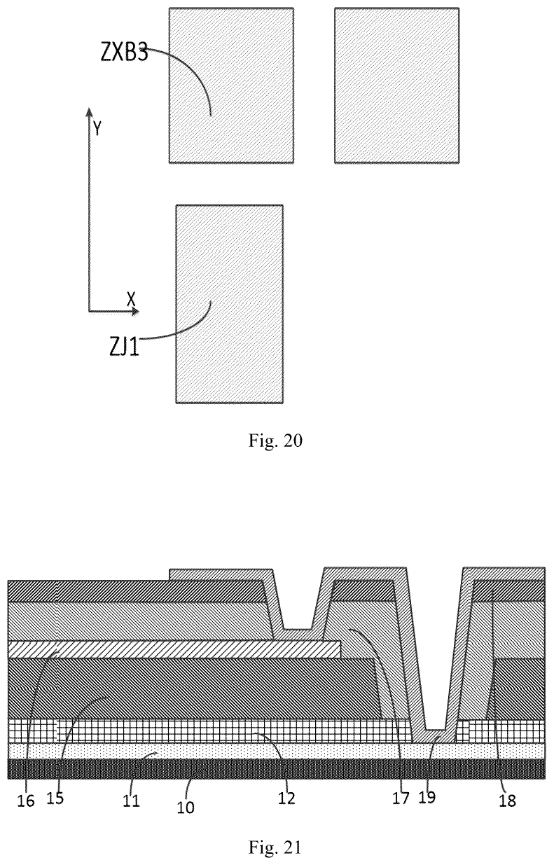

FIG. 17 is a plan layout view of two first signal lines in a display panel according to at least one embodiment, FIG. 18 is a plan layout view of a light shading metal layer in FIG. 17, FIG. 19 is a plan layout view of a source-drain metal layer of FIG. 17, and FIG. 20 is a plan layout view of a pixel electrode layer of FIG. 17.

As shown in FIGS. 17 to 20, the first one of the first signal lines includes a first signal body line part ZX1, and the second one of the first signal lines includes a second signal body line part ZX2.

The first signal body line part may include a first body line portion ZXB1, a second body line portion ZXB2, and a third body line portion ZXB3.

The ZXB1 may be located in the light shading metal layer, the ZXB2 may be located in the source-drain metal layer, and the ZXB3 may be located in the pixel electrode layer.

An orthographic projection of the third body line portion ZXB3 onto the base at least partially overlaps with an orthographic projection of the first body line portion ZXB1 onto the base, and the orthographic projection of the third body line portion ZXB3 onto the base at least partially overlaps with an orthographic projection of the second body line portion ZXB2 onto the base.

The third body line portion ZXB3 is electrically connected to the second body line portion ZXB2 through a fifth via hole H5, and the third body line portion ZXB3 is electrically connected to the first body line portion ZXB1 through a sixth via hole H6.

In at least one embodiment of the present disclosure, the first signal line further includes a first transition part; an orthographic projection of the first transition part onto the base at least partially overlaps with an orthographic projection, onto the base, of the signal connecting wire part included by the first signal line to which the cross-line part belongs; the orthographic projection of the first transition part onto the base at least partially overlaps with the orthographic projection of the cross-line part onto the base;
the first transition part is electrically connected to the signal connecting wire part through a seventh via hole, and the first transition part is electrically connected to the cross-line part through an eighth via hole; and
the first transition part and the signal connecting wire are located in different layers, and the first transition part and the cross-line part are located in different conductive layers.

In a particular implementation, the first signal line may further include a first transition part, the first transition part may be electrically connected to the signal connecting wire part through a seventh via hole, and the first transition part may be electrically connected to the cross-line part through an eighth via hole.

Optionally, the first transition part is located in the fourth conductive layer.

As shown in FIGS. 17 to 20, the first one of the first signal lines includes a cross-line part LK1 and a first signal connecting wire part LX1; and
the second one of the first signal lines includes a second signal connecting wire part LX2.

An orthographic projection of the cross-line part LK1 onto the base partially overlaps with an orthographic projection of the second signal connecting wire part LX2 onto the base.

The cross-line part LK1 is formed in a source-drain metal layer, and the first signal connecting wire part LX1 and the second signal connecting wire part LX2 are formed in a light shading metal layer.

The first signal connecting wire part LX1 and the second signal connecting wire part LX2 extend in the vertical direction.

The first one of the first signal lines further includes a first transition part ZJ1.

The first transition part ZJ1 is located in the pixel electrode layer.

An orthographic projection of the first transition part ZJ1 onto the base at least partially overlaps with an orthographic projection of the first signal connecting wire part LX1 onto the base. The orthographic projection of the first transition part ZJ1 onto the base at least partially overlaps with the orthographic projection of the cross-line part LX1 onto the base.

The first transition part ZJ1 is electrically connected to the first signal connecting wire part LX1 through a seventh via hole H7, and the first transition part ZJ1 is electrically connected to the cross-line part LK1 through an eighth via hole H8.

FIG. 21 is a cross-sectional view taken along line E-E′ in FIG. 17.

As shown in FIGS. 17 to 21, the specific process for fabricating the first signal lines shown in FIG. 17 is basically consistent with the related process. That is, the etching time for the interlayer dielectric layer is not changed, a connection hole region is formed above the light shading metal layer in the form of a stacked hole (an interlayer dielectric layer hole+a passivation layer hole), and a passivation layer hole is opened above the source-drain metal layer, as a result, when the pixel electrode layer is formed as a film, the light shading metal layer and the source-drain metal layers are overlapped and connected, and the climbing of the pixel electrode layer is intact.

In FIG. 21, reference numeral 10 denotes a base, reference numeral 11 denotes a light shading metal layer, reference numeral 12 denotes a buffer layer, reference numeral 15 denotes an interlayer dielectric layer, reference numeral 16 denotes a source-drain metal layer, reference numeral 17 denotes a first passivation layer, reference numeral 18 denotes a second passivation layer, and reference numeral 19 denotes a pixel electrode layer.

In practical operation, the taper angle and the over-etching situation of the gate insulating layer after dry etching of the gate insulating layer, corresponding to the gate metal layer with different line widths, are measured, and it is found that, the situation where the taper angle of the gate insulating layer is poor and the gate insulating layer is over-etched only occurs when the line width of the signal connecting wire part formed in the gate metal layer is relatively large. Thus, in at least one embodiment of the present disclosure, the signal connecting wire part may be configured to include multiple signal connecting wire portions extending in a first direction, and a width, in a second direction, of the signal connecting wire portion is less than a width threshold. For example, the line width of the signal connecting wire portion may be greater than or equal to 4 μm and less than or equal to 6 μm, to ensure that the sheet resistance of the first signal line as a whole is at its original level.

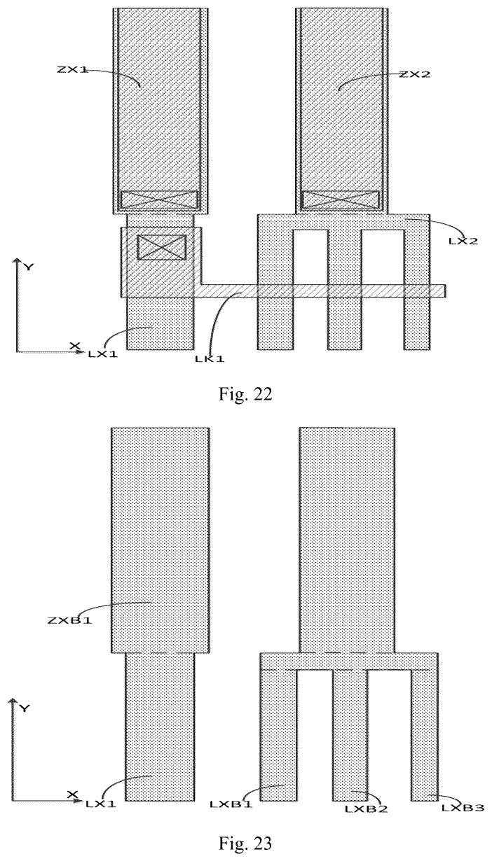

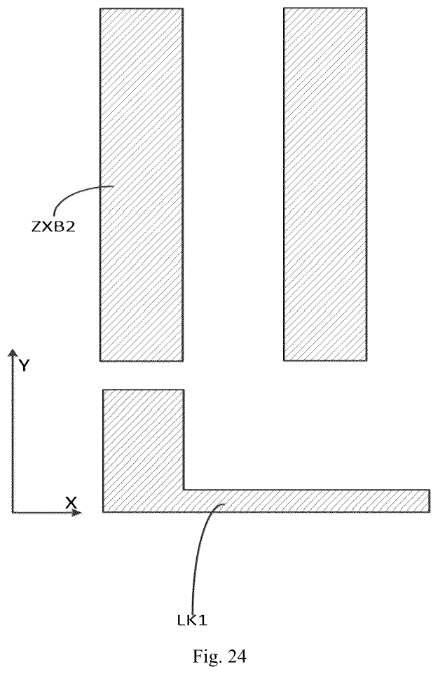

FIG. 22 is a plan layout view of two first signal lines in a display panel according to at least one embodiment, FIG. 23 is a plan layout view of the gate metal layer of FIG. 22, and FIG. 24 is a plan layout view of the source-drain metal layer of FIG. 22.

As shown in FIGS. 22 to 24, the first one of the first signal lines includes a cross-line part LK1 and a first signal connecting wire part LX1.

The second one of the first signal lines includes a second signal connecting wire part LX2.

LK1 is located in the source-drain metal layer, and LX1 and LX2 are formed in the gate metal layer.

The second signal connecting wire part includes a first signal connecting wire portion LXB1, a second signal connecting wire portion LXB2, and a third signal connecting wire portion LXB3.

The LXB1, the LXB2 and the LXB3 all extend in the vertical direction, and the LXB1, the LXB2 and the LXB3 are all located in the gate metal layer.

The width, in the horizontal direction, of the LXB1, the width, in the horizontal direction, of the LXB2, and the width, in the horizontal direction, of the LXB3 each may be greater than or equal to 4 μm and less than or equal to 6 μm.

The orthographic projection of LK1 onto the base partially overlaps with the orthographic projection of LXB1 onto the base, the orthographic projection of LK1 onto the base partially overlaps with the orthographic projection of LXB2 onto the base, and the orthographic projection of LK1 onto the base partially overlaps with the orthographic projection of LXB3 onto the base.

As shown in FIGS. 22 to 24, the first one of the first signal lines includes a first signal body line part ZX1, and the second one of the first signal lines includes a second signal body line part ZX2.

The first signal body line part may include a first body line portion ZXB1 and a second body line portion ZXB2.

The ZXB1 is located in the gate metal layer, and the ZXB2 is located in the source-drain metal layer.

ZXB1 is electrically connected to ZXB2 through a via hole, the cross-line part LK1 is electrically connected to LX1 through a via hole, and the orthographic projection of LK1 onto the base partially overlaps with the orthographic projection of LX1 onto the base.

In the above embodiments, the first signal line may be applied to a display panel, and the GOA circuit of the display panel includes a Top-gate self-alignment TFT (thin film transistor).

In at least one embodiment of the present disclosure, the structure of the first signal line may be applied to a display panel, and the GOA circuit in the display panel may include a BCE (back channel etching type) TFT with a metal auxiliary layer.

In a BCE (back channel etching type) TFT with a metal auxiliary layer, a metal auxiliary layer may be added in the BCE TFT, which is referred to as an M3 layer, and the M3 layer is directly coated on a common electrode layer, and the common electrode layer may be made of, for example, ITO, so as to reduce the sheet resistance of the common electrode layer, thereby reducing crosstalk defects and improving display product yield. At least one embodiment of the present disclosure may use a solution where the M3 process is adopted to improve the AD defect of the first signal line, i.e. in the first signal line region, the cross-line part may be configured to be located in the metal auxiliary layer, so that the cross-line part and the signal connecting wire part are spaced apart by at least one insulating layer, the thickness of the insulating layer between the cross-line part and the signal connecting wire part is increased, and the incidence of AD of the first signal line is reduced.

In at least one embodiment of the present disclosure, the display panel includes a second conductive layer, a third conductive layer, a fifth conductive layer, a sixth conductive layer, and a fourth conductive layer that are sequentially arranged in a direction away from the base; the fifth conductive layer is overlapped and connected with the sixth conductive layer; at least one insulating layer is provided between the second conductive layer and the third conductive layer, at least one insulating layer is provided between the third conductive layer and the fifth conductive layer, and at least one insulating layer is provided between the sixth conductive layer and the fourth conductive layer; and
at least a portion of the cross-line part is located in the sixth conductive layer, and the signal connecting wire part is located in the second conductive layer.

In at least one embodiment of the present disclosure, the second conductive layer includes a gate line provided in the display region, the third conductive layer includes a data line provided in the display region, the fifth conductive layer includes a common electrode provided in the display region, and the sixth conductive layer includes an auxiliary metal pattern provided in the display region.

Optionally, the second conductive layer may be a gate metal layer, the third conductive layer may be a source-drain metal layer, the fifth conductive layer may be a common electrode layer, the sixth conductive layer may be a metal auxiliary layer, and the fourth conductive layer may be a pixel electrode layer.

The common electrode layer may be directly overlapped and connected with the metal auxiliary layer.

At least part of the cross-line part may be located in the metal auxiliary layer, and the signal connecting wire part may be located in the gate metal layer, but the present disclosure is not limited thereto.

In at least one embodiment of the present disclosure, the metal auxiliary layer may be made of copper, and the gate metal layer and the source-drain metal layer may also be made of copper, but the present disclosure is not limited thereto.

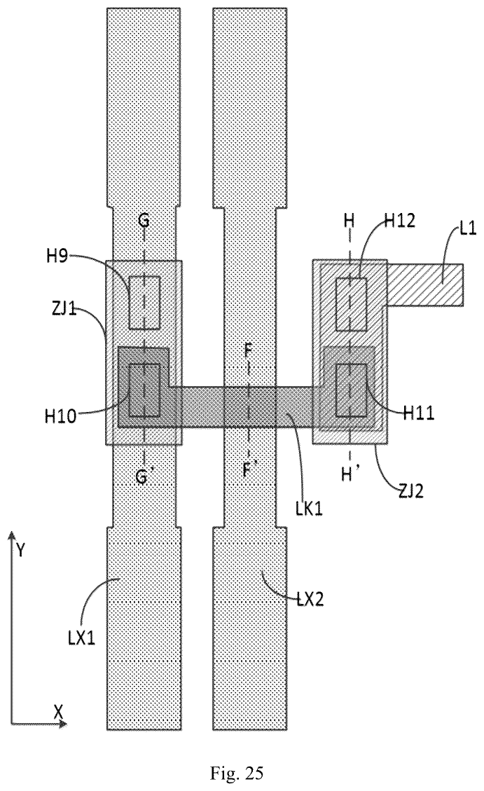

As shown in FIGS. 25 to 29A, the first one of the first signal lines includes a first signal connecting wire part LX1 and a cross-line part LK1;
the second one of the first signal lines includes a second signal connecting wire part LX2; and
LX1 and LX2 are located in the gate metal layer, and LK1 is located in the metal auxiliary layer.

At least one embodiment shown in FIG. 25 is simple and feasible, without the need of increasing the quantity of masks (Mask), and the incidence of AD of the first signal line can be significantly reduced. In at least one embodiment shown in FIG. 25, in the first signal cross-line region, the insulating layers between the cross-line part LK 1 and the first signal connecting wire part LX1 includes a gate insulating layer and a first passivation layer, the thickness of the gate insulating layer and the thickness of the first passivation layer are about 4000 Å and 5000 Å, respectively. In at least one embodiment of the present disclosure, the thickness of the insulating layers in the first signal cross-line region has more than doubled, which can significantly reduce the AD issue of the first signal line caused by copper interconnects.

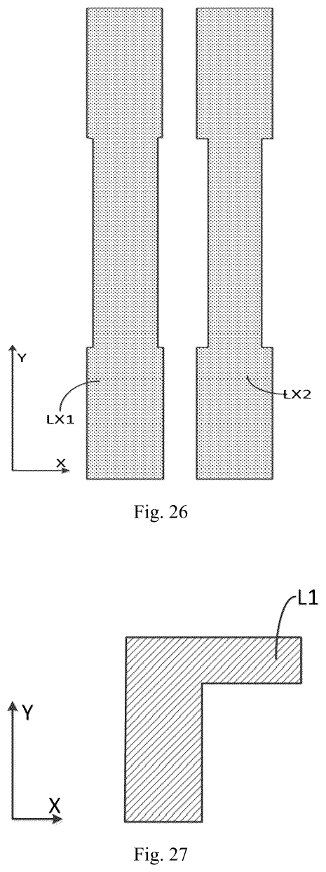

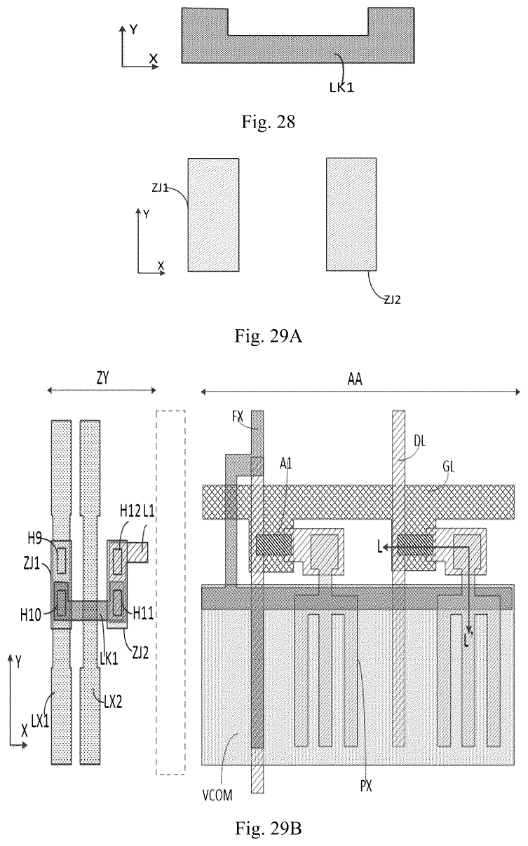

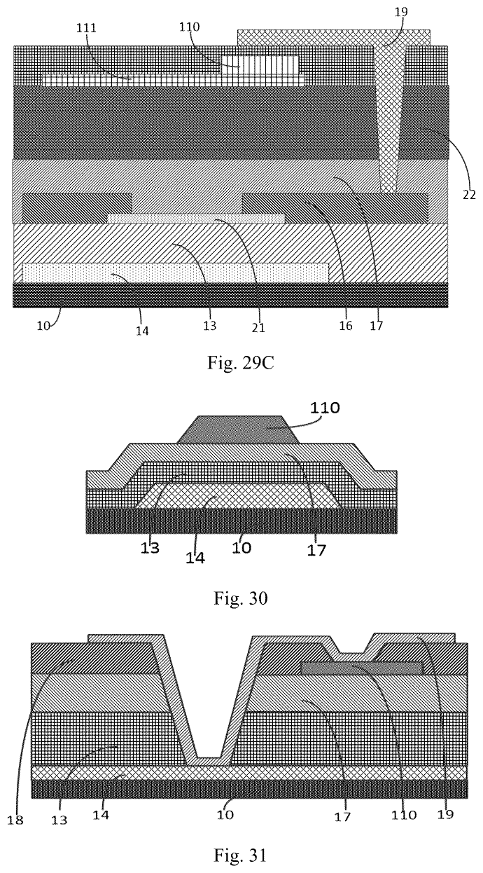

FIG. 26 is a plan layout view of a gate metal layer of FIG. 25, FIG. 27 is a plan layout view of a source metal layer of FIG. 25, FIG. 28 is a plan layout view of a metal auxiliary layer of FIG. 25, and FIG. 29A is a plan layout view of a pixel electrode layer of FIG. 25.

In at least one embodiment of the present disclosure, the thickness of the metal auxiliary layer may be about 3000 Å, but the present disclosure is not limited thereto.

In at least one embodiment of the present disclosure, the first signal line further includes a first transition part;
the first transition part is electrically connected to the signal connecting wire part through a ninth via hole, and the first transition part is electrically connected to the cross-line part through a tenth via hole; and
the first transition part and the signal connecting wire part are located in different layers, and the first transition part and the cross-line part are located in different conductive layers.

Optionally, the first transition part is located in the fourth conductive layer.

As shown in FIGS. 25 to 29A, the first one of the first signal lines may further include a first transition part ZJ1.

The first transition part ZJ1 may be located in the pixel electrode layer.

ZJ1 is electrically connected to the first signal connecting wire part LX1 through a ninth via hole H9, and ZJ1 is electrically connected to the cross-line part LK1 through a tenth via hole H10.

The orthographic projection of ZJ1 onto the base partially overlaps with the orthographic projection of LX1 onto the base, and the orthographic projection of ZJ1 onto the base partially overlaps with the orthographic projection of the cross-line part LK1 onto the base.

In at least one embodiment of the present disclosure, the first signal line further includes a third transition part and a connecting wire;
the third transition part is electrically connected to the cross-line part through an eleventh via hole, and the third transition part is electrically connected to the connecting wire through a twelfth via hole; and
the third transition part and the cross-line part are located in different conductive layers, and the third transition part and the connecting wire are located in different conductive layers.

Optionally, the third transition part is located in the fourth conductive layer, and the connecting wire is located in the third conductive layer.

In a particular implementation, the first signal line may further include a third transition part and a connecting wire, the third transition part may be located in a pixel electrode layer, and the connecting wire may be located in a source-drain metal layer.

The third transition part may be electrically connected to the cross-line part through an eleventh via hole, and the third transition part may be electrically connected to the connecting wire through a twelfth via hole.

The connecting wire may be electrically connected to at least one TFT in the GOA circuit.

The third transition part, the eleventh via hole and the twelfth via hole may be provided between the wiring region of the first signal line and the distribution region of the GOA TFT (the GOA TFT may be a TFT in the GOA circuit).

As shown in FIGS. 25 to 29A, the first one of the first signal lines may further include a third transition part ZJ3 and a connecting wire L1.

The third transition part ZJ3 is located in the pixel electrode layer, and the connecting wire L1 is located in the source-drain metal layer.

The third transition part ZJ3 is electrically connected to the cross-line part LK1 through an eleventh via hole H11, and the third transition part ZJ3 is electrically connected to the connecting wire L1 through a twelfth via hole H12.

FIG. 30 is a cross-sectional view taken along line F-F′ in FIG. 25.

In FIG. 30, reference numeral 10 denotes a base, reference numeral 14 denotes a gate metal layer, reference numeral 13 denotes a gate insulating layer, reference numeral 17 denotes a first passivation layer, and reference numeral 110 denotes a metal auxiliary layer.

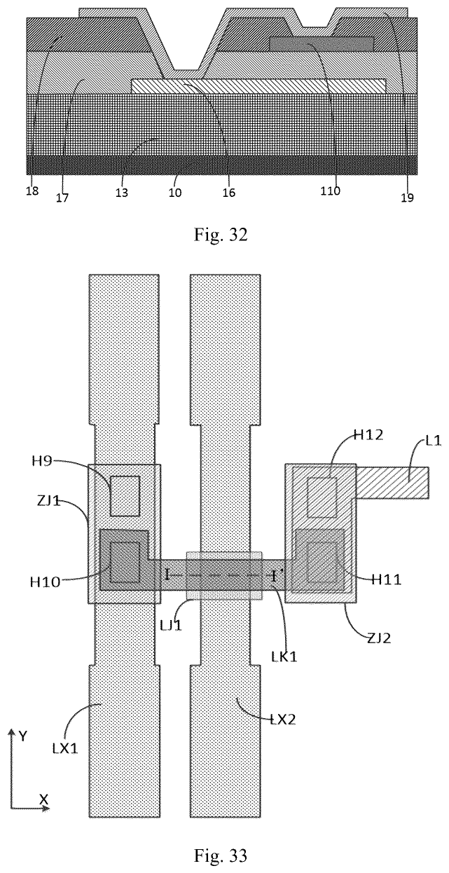

FIG. 31 is a cross-sectional view taken along line G-G′ in FIG. 25, and FIG. 32 is a cross-sectional view taken along line H-H′ in FIG. 25.

In FIGS. 31 and 32, reference numeral 10 denotes a base, reference numeral 13 denotes a gate insulating layer, reference numeral 14 denotes a gate metal layer, reference numeral 16 denotes a source-drain metal layer, reference numeral 17 denotes a first passivation layer, reference numeral 18 denotes a second passivation layer, reference numeral 19 denotes a pixel electrode layer, and reference numeral 110 denotes a metal auxiliary layer.

As shown in FIG. 29B, two first signal lines shown in FIG. 25 are provided in a peripheral region ZY, and a gate line GL, a data line DL and a transistor in a sub-pixel are provided in a display region AA.

In FIG. 29B, reference sign Al denotes an active pattern of the transistor, reference sign VCOM denotes a common electrode, reference sign FX denotes an auxiliary metal pattern, and reference sign PX denotes a pixel electrode.

In at least one embodiment corresponding to FIG. 29B, the active pattern Al of the transistor is located in the semiconductor layer, the pixel electrode PX is located in the pixel electrode layer, the common electrode VCOM is located in the common electrode layer, and the auxiliary metal pattern FX is located in the metal auxiliary layer; the gate line GL is located in the gate metal layer, and the data line DL is located in the source-drain metal layer.

FIG. 29C is a cross-sectional view taken along line L-L′ in FIG. 29B.

In FIG. 29C, reference numeral 10 denotes a base, reference numeral 21 denotes a semiconductor layer, reference numeral 13 denotes a gate insulating layer, reference numeral 14 denotes a gate metal layer, reference numeral 16 denotes a source-drain metal layer, reference numeral 17 denotes a first passivation layer, reference numeral 22 denotes an organic layer, reference numeral 110 denotes a metal auxiliary layer, reference numeral 111 denotes a common electrode layer, reference numeral 18 denotes a second passivation layer, and reference numeral 19 denotes a pixel electrode layer.

In at least one embodiment of the present disclosure, the first signal line further includes a first connecting part located in the fifth conductive layer; the first connecting part is overlapped and connected with the cross-line part;
an orthographic projection of the first connecting part onto the base covers an orthographic projection of a cross-line region onto the base; and
the cross-line region is an overlap region between the cross-line part and the signal connecting wire part included by at least a portion of the multiple second sub-signal lines.

In a particular implementation, the first signal line may further include a first connecting part, the first connecting part may be located in a common electrode layer, the first connecting part is directly overlapped and connected with the cross-line part, and the orthographic projection of the first connecting part onto the base may cover the orthographic projection of the cross-line region onto the base.

As shown in FIG. 33, on the basis of at least one embodiment shown in FIG. 25, the first one of the first signal lines may further include a first connecting part LJ1.

The first connecting part LJ1 may be located in the common electrode layer.

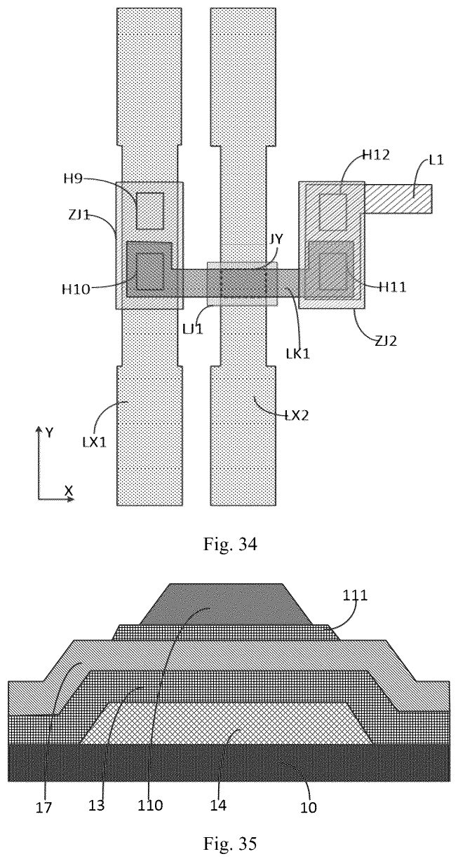

In FIG. 34, a reference sign JY denotes an overlap region between the cross-line part LK1 and the second signal connecting wire part LX2.

As shown in FIGS. 33 and 34, the orthographic projection of the first connecting part LJ1 onto the base covers the orthographic projection of the overlap region JY onto the base, so as to further enhance the ability to resist copper diffusion, and reduce the occurrence probability of AD of the first signal. In at least one embodiment of the present disclosure, no additional process is added, only the mask pattern of the common electrode layer needs to be changed, and the improvement effect on AD of the first signal line is better.

As shown in FIGS. 33 and 34, in the cross-line region, the line width of the first connecting part LJ1 may be greater than the line width of the cross-line part LK1 by 1 μm to 1.5 μm, so that the orthographic projection of the first connecting part LJ1 onto the base may cover the orthographic projection of the overlap region JY onto the base.

FIG. 35 is a cross-sectional view taken along line I-I′ in FIG. 33.

In FIG. 35, reference numeral 10 denotes a base, reference numeral 14 denotes a gate metal layer, reference numeral 13 denotes a gate insulating layer, reference numeral 17 denotes a first passivation layer, and reference numeral 110 denotes a metal auxiliary layer, and reference numeral 111 denotes a common electrode layer.

In at least one embodiment of the present disclosure, the first signal line further includes a first transition part and a second transition part; the second transition part is overlapped and connected with the cross-line part;
the first transition part is electrically connected to the signal connecting wire part through a thirteenth via hole, and the first transition part is electrically connected to the second transition part through a fourteenth via hole; and
the first transition part and the signal connecting wire part are located in different layers, and the first transition part and the second transition part are located in different conductive layers.

In a particular implementation, the first signal line may further include a first transition part and a second transition part, the first transition part may be located in a pixel electrode layer, the second transition part may be located in a common electrode layer, and the second transition part may be directly overlapped and connected with the cross-line part. The first transition part may be electrically connected to the signal connecting wire part through a thirteenth via hole, and the first transition part may be electrically connected to the second transition part through a fourteenth via hole, such that the signal connecting wire part is electrically connected to the cross-line part.

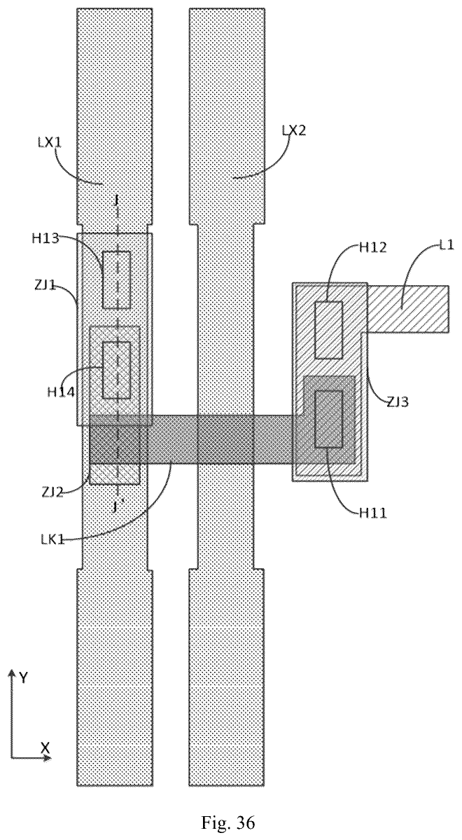

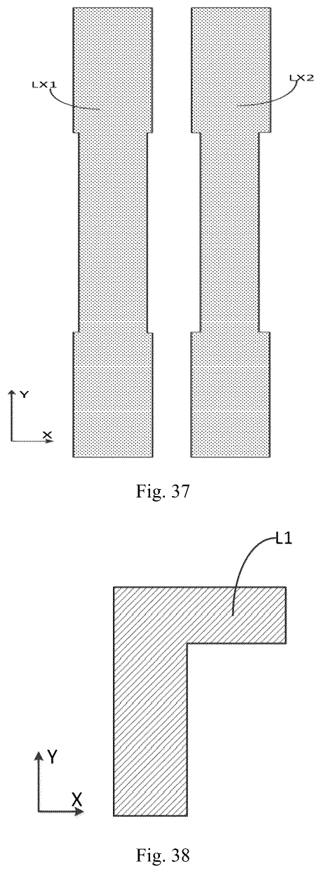

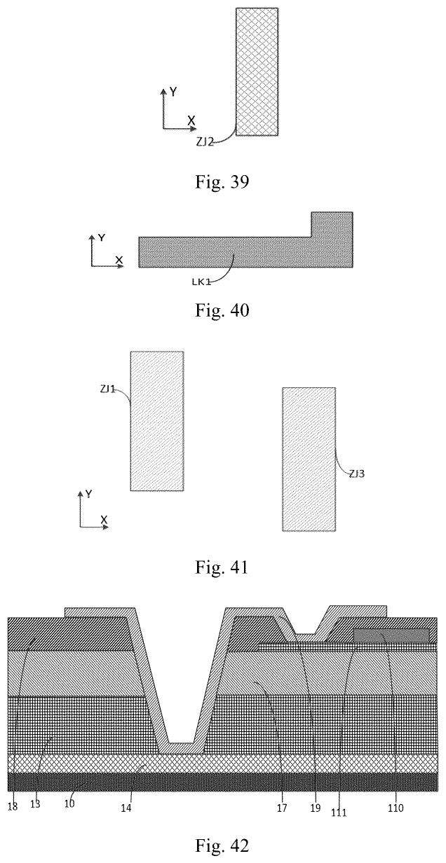

FIG. 37 is a plan layout view of a gate metal layer of FIG. 36, FIG. 38 is a plan layout view of a source-drain metal layer of FIG. 36, FIG. 39 is a plan layout view of a common electrode layer of FIG. 36, FIG. 40 is a plan layout view of a metal auxiliary layer of FIG. 36, and FIG. 41 is a plan layout view of a pixel electrode layer of FIG. 36.

As shown in FIGS. 36 to 41, the first one of the first signal lines includes a cross-line part LK1, a first signal connecting wire part LX1, a first transition part ZJ1, and a second transition part ZJ2. The second one of the first signal lines includes a second signal connecting wire part LX2.

LX1 is located in a gate metal layer, ZJ1 is located in a pixel electrode layer, ZJ2 is located in a common electrode layer, and LK1 is located in a metal auxiliary layer.

The second transition part ZJ2 is directly overlapped and connected with the cross-line part LK1.

The first transition part ZJ1 is electrically connected to the first signal connecting wire part LX1 through a thirteenth via hole H13, and the first transition part ZJ1 is electrically connected to the second transition part ZJ2 through a fourteenth via hole H14.

The orthographic projection of ZJ1 onto the base partially overlaps with the orthographic projection of the first signal connecting wire part LX1 onto the base, and the orthographic projection of ZJ1 onto the base partially overlaps with the orthographic projection of ZJ2 onto the base.

The second one of the first signal lines may include a second signal connecting wire part LX2.

LX2 may be located in the gate metal layer.

As shown in FIGS. 36 to 41, the first one of the first signal lines may further include a third transition part ZJ3 and a connecting wire L1.

The third transition part ZJ3 is located in the pixel electrode layer, and the connecting wire L1 is located in the source-drain metal layer.

The third transition part ZJ3 is electrically connected to the cross-line part LK1 through an eleventh via hole H11, and the third transition part ZJ3 is electrically connected to the connecting wire L1 through a twelfth via hole H12.

As shown in FIGS. 36 to 41, ZJ3 may be located in the pixel electrode layer, and L1 may be located in the source-drain metal layer.

FIG. 42 is a cross-sectional view taken along line J-J′ in FIG. 36.

In at least one embodiment of the present disclosure, the cross-line part includes a first cross-line portion and a second cross-line portion;
an orthographic projection of the first cross-line portion onto the base covers an orthographic projection of the second cross-line portion onto the base; and
the first cross-line portion is directly overlapped and connected with the second cross-line portion.

Optionally, the first cross-line portion is located in the fifth conductive layer, and the second cross-line portion is located in the sixth conductive layer.

In a particular implementation, the cross-line part may include a first cross-line portion located in the common electrode layer and a second cross-line portion located in the metal auxiliary layer, and the first cross-line portion may be directly overlapped and connected with the second cross-line portion.

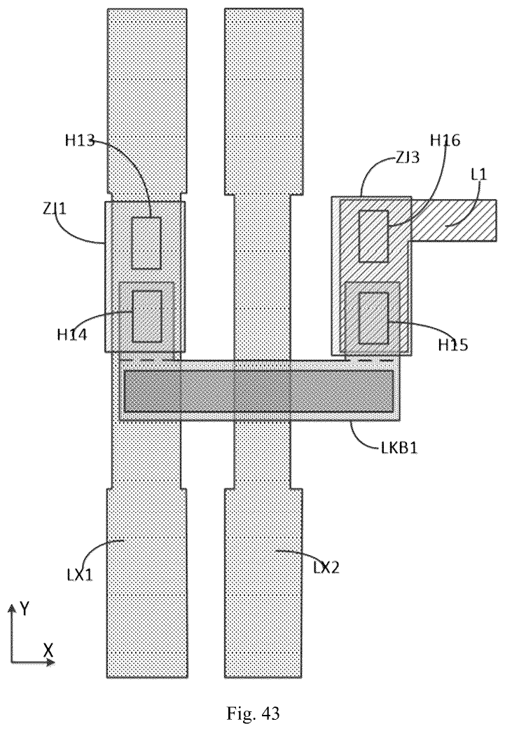

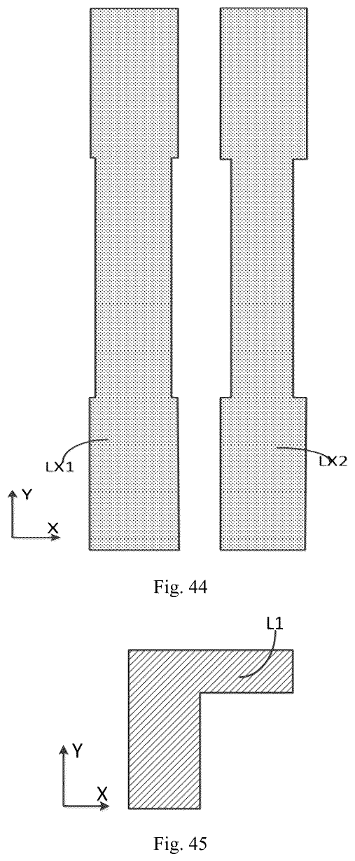

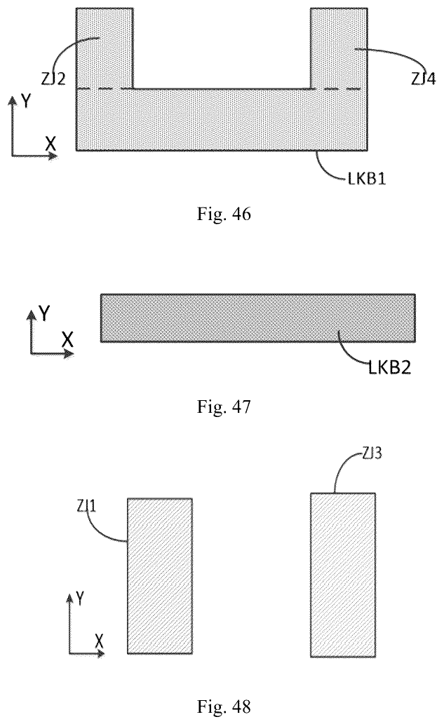

FIG. 44 is a plan layout view of a gate metal layer of FIG. 43, FIG. 45 is a plan layout view of a source-drain metal layer of FIG. 43, FIG. 46 is a plan layout view of a common electrode layer of FIG. 43, FIG. 47 is a plan layout view of a metal auxiliary layer of FIG. 43, and FIG. 48 is a plan layout view of a pixel electrode layer of FIG. 43.

As shown in FIGS. 43 to 48, the first one of the first signal lines may include a first signal connecting wire part LX1 and a cross-line part.

The second one of the first signal lines may include a second signal connecting wire part LX2.

The cross-line part includes a first cross-line portion LKB1 and a second cross-line portion LKB2.

The LKB1 may be located in a common electrode layer, and the LKB2 may be located in a metal auxiliary layer.

The orthographic projection of LKB1 onto the base covers the orthographic projection of the second cross-line portion LKB2 onto the base to ensure that the orthographic projection of LKB1 onto the base covers the overlap region of LKB2 and LX2.

In at least one embodiment shown in FIGS. 43 to 48, in the cross-line region, the line width of LKB1 may be 1 μm to 1.5 μm greater than the line width of LKB2.

In at least one embodiment of the present disclosure, the first signal line further includes a first transition part and a second transition part; the second transition part is electrically connected to the first cross-line portion;
the first transition part is electrically connected to the signal connecting wire part through a thirteenth via hole, and the first transition part is electrically connected to the second transition part through a fourteenth via hole; and
the first transition part and the signal connecting wire part are located in different conductive layers, and the first transition part and the second transition part are located in different conductive layers.

As shown in FIGS. 43 to 48, the first one of the first signal lines may further include a first transition part ZJ1 and a second transition part ZJ2, ZJ1 may be located in a pixel electrode layer, and ZJ2 may be located in a common electrode layer.

The second transition part ZJ2 may be electrically connected to the first cross-line portion LKB1.

The first transition part ZJ1 is electrically connected to the first signal connecting wire part LX1 through a thirteenth via hole H13, and the first transition part ZJ1 is electrically connected to the second transition part ZJ2 through a fourteenth via hole H14.

The orthographic projection of ZJ1 onto the base partially overlaps with the orthographic projection of LX1 onto the base, and the orthographic projection of ZJ1 onto the base partially overlaps with the orthographic projection of ZJ2 onto the base.

In at least one embodiment of the present disclosure, the first signal line further includes a third transition part, a fourth transition part, and a connecting wire;
the fourth transition part is electrically connected to the first cross-line portion; the fourth transition part and the first cross-line portion are located in a same conductive layer;
the third transition part is electrically connected to the fourth transition part through a fifteenth via hole, and the third transition part is electrically connected to the connecting wire through a sixteenth via hole; and
the third transition part and the fourth transition part are located in different conductive layers, and the third transition part and the connecting wire are located in different conductive layers.

Optionally, the third transition part is located in the fourth conductive layer, and the fourth transition part is located in the fifth conductive layer. The connecting wire is located in the third conductive layer.

As shown in FIGS. 43 to 48, the first one of the first signal lines may further include a third transition part ZJ3, a fourth transition part ZJ4, and a connecting wire L1.

ZJ3 may be located in a pixel electrode layer, and ZJ4 may be located in a common electrode layer.

ZJ4 may be electrically connected to LKB1.

ZJ3 is electrically connected to the fourth transition part ZJ4 through a fifteenth via hole H15, and the ZJ3 is electrically connected to the connecting wire L1 through a sixteenth via hole H16.

L1 may be located in the source-drain metal layer.

ZJ3, ZJ4, H15, and H16 may be provided between the wiring region of the first signal line and the distribution region of the GOA TFT (the GOA TFT may be a TFT in the GOA circuit).

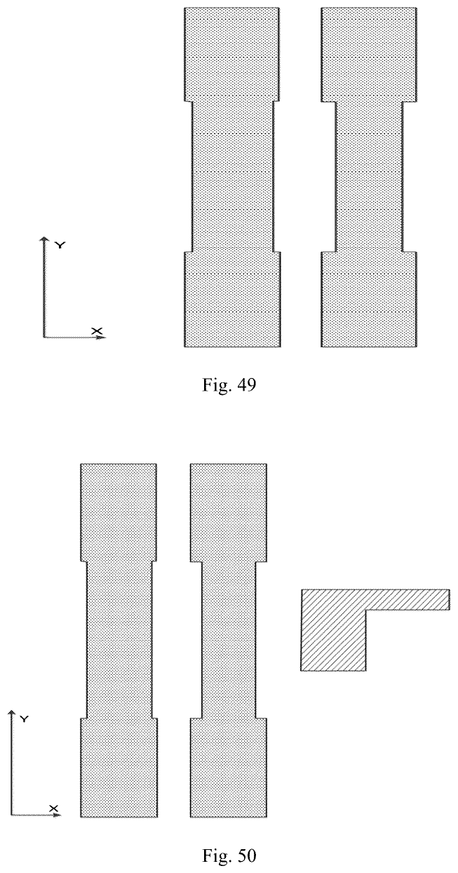

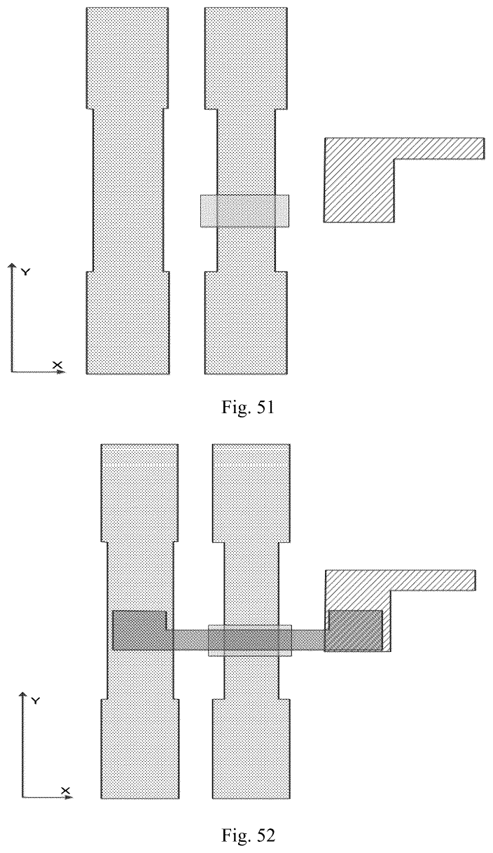

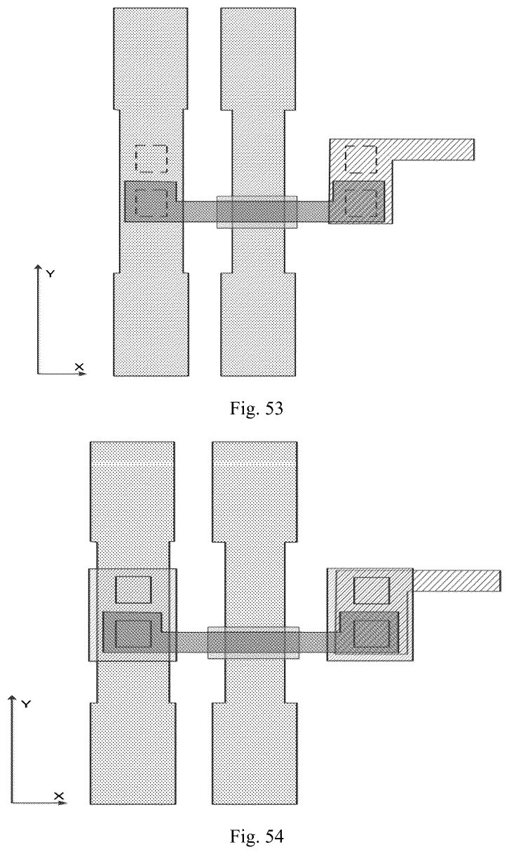

In fabricating the first signal lines shown in FIG. 33, the specific process is as follows:
1, a gate metal layer is formed as a film to obtain the pattern shown in FIG. 49;
2, a gate insulating layer is formed as a film, a semiconductor layer is formed as a film and etched, and a source-drain metal layer is formed as a film and etched, to obtain the pattern shown in FIG. 50;
3, a first passivation layer is formed as a film, an organic layer is coated, exposed and developed, and a common electrode layer is formed as a film and is etched, to obtain the pattern shown in FIG. 51;
4, a metal auxiliary layer is formed as a film and etched to obtain the pattern shown in FIG. 52;
5, a second passivation layer is formed as a film, and is etched according to the region shown by the dotted lines in FIG. 53, reserving connection hole regions for the metal auxiliary layer, the gate metal layer, and the source-drain metal layer; and
6, a pixel electrode layer is formed as a film and etched to obtain the pattern shown in FIG. 54.

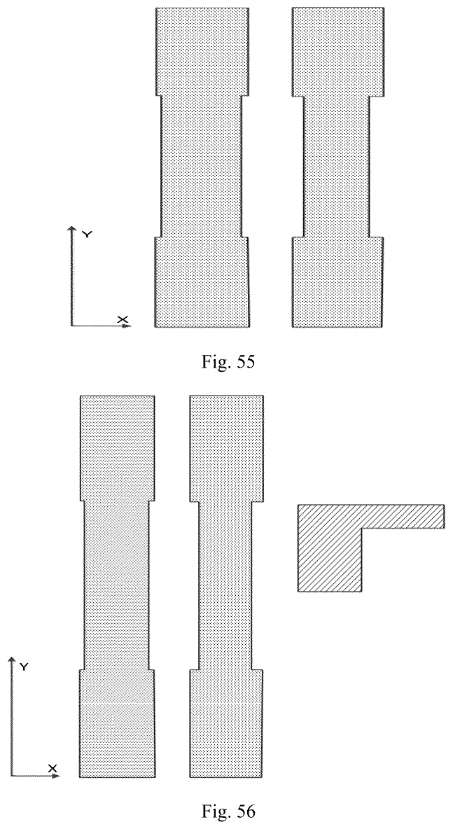

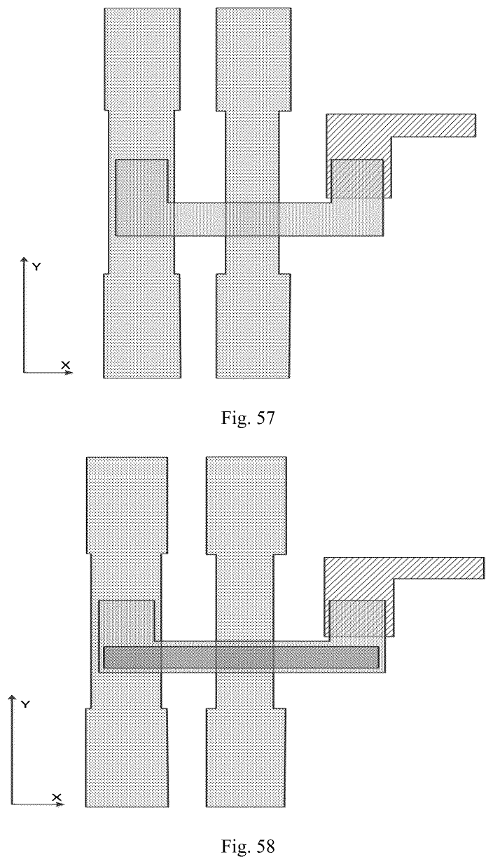

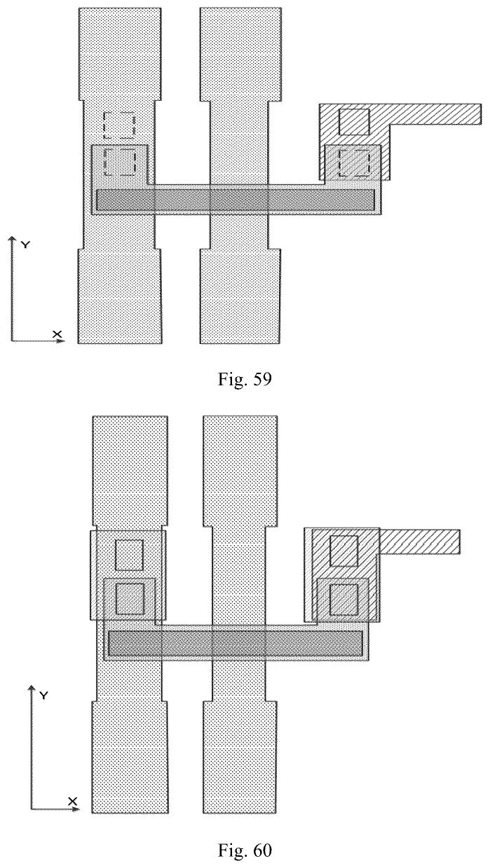

In fabricating the first signal lines shown in FIG. 43, the specific process is as follows:
1, a gate metal layer is formed as a film and etched to obtain the pattern shown in FIG. 55;
2, a gate insulating layer is formed as a film, a semiconductor layer is formed as a film and etched, and a source-drain metal layer is formed as a film and etched, to obtain the pattern shown in FIG. 56;
3, a first passivation layer is formed as a film, an organic layer is coated, exposed and developed, a common electrode layer is formed as a film and is etched, to obtain the pattern shown in FIG. 57;
4, a metal auxiliary layer is formed as a film and etched to obtain the pattern shown in FIG. 58;
5, a second passivation layer is formed as a film, and is etched according to the region shown by the dotted lines in FIG. 59, reserving connection hole regions for the common electrode layer, the gate metal layer, and the source-drain metal layer; and
6, a pixel electrode layer is formed as a film and etched to obtain the pattern shown in FIG. 60.

A display device according to embodiments of the present disclosure includes the display panel described in the above.

Preferred embodiments of the present disclosure are described in the above. It should be noted that those skilled in the art may make various improvements and modifications to the present disclosure, without departing from the principle of the present disclosure, and these improvements and modifications shall fall within the protection scope of the present disclosure.

1. A display panel, comprising a display region and a peripheral region surrounding the display region, wherein a plurality of first signal lines located on a base are provided within the peripheral region; each first signal line of the plurality of first signal lines comprises a signal connecting wire part;
wherein the plurality of first signal lines is divided into a first sub-signal line and second sub-signal lines, wherein the first sub-signal line comprises a cross-line part, and each of the second sub-signal lines does not comprise a cross-line part;
wherein an orthographic projection of the cross-line part onto the base partially overlaps with an orthographic projection of at least a portion of the plurality of second sub-signal lines onto the base;
wherein the cross-line part and the signal connecting wire part comprised by at least a portion of the plurality of second sub-signal lines are spaced apart by at least two insulating layers; and/or, the signal connecting wire part comprised by at least a portion of the plurality of second sub-signal lines comprises a plurality of signal connecting wire portions extending in a first direction, where each of the plurality of signal connecting wire portions has a width in a second direction less than a width threshold; and
wherein the signal connecting wire part extends in the first direction, and the second direction intersects with the first direction.

2. The display panel according to claim 1, wherein the width threshold is greater than or equal to 5 μm and less than or equal to 8 μm.

3. The display panel according to claim 1, comprising a first conductive layer, a second conductive layer, and a third conductive layer that are sequentially arranged in a direction away from the base; wherein at least one insulating layer is provided between adjacent conductive layers; and
wherein the cross-line part is located in the third conductive layer, and the signal connecting wire part is located in the first conductive layer.

4. The display panel according to claim 3, wherein the first conductive layer comprises a light shading pattern provided in the display region, the second conductive layer comprises a gate line provided in the display region, and the third conductive layer comprises a data line provided in the display region.

5. The display panel according to claim 3, wherein the first signal line further comprises a signal body line part;
wherein the signal body line part comprises a first body line portion, a second body line portion, and a third body line portion; the first body line portion, the second body line portion, and the third body line portion are located in different conductive layers;
wherein the third body line portion is electrically connected to the second body line portion through a first via hole; and
wherein an orthographic projection of the first body line portion onto the base, an orthographic projection of the second body line portion onto the base, and an orthographic projection of the third body line portion onto the base at least partially overlap.

6. The display panel according to claim 5, wherein the first signal line further comprises a signal lead wire part;
wherein the signal lead wire part is provided between the signal body line part and the signal connecting wire part;
wherein the signal lead wire part comprises a first lead wire portion and a second lead wire portion that are located in different conductive layers;
wherein the first lead wire portion is electrically connected to the second lead wire portion through a second via hole; and
wherein an orthographic projection of the first lead wire portion onto the base at least partially overlaps with an orthographic projection of the second lead wire portion onto the base.

7. The display panel according to claim 6, wherein the signal connecting wire part, the first body line portion, and the first lead wire portion are electrically connected, and the third body line portion and the second lead wire portion are electrically connected.

8. The display panel according to claim 3, wherein the first signal line further comprises a signal body line part;
wherein the signal body line part comprises a first body line portion and a second body line portion that are located in different conductive layers;
wherein the first body line portion is electrically connected to the second body line portion through a third via hole; and
wherein an orthographic projection of the first body line portion onto the base and an orthographic projection of the second body line portion onto the base at least partially overlap.

9. The display panel according to claim 8, wherein the signal connecting wire part is electrically connected to the first body line portion.

10. The display panel according to claim 5, wherein the orthographic projection of the cross-line part onto the base partially overlaps with an orthographic projection, onto the base, of the signal connecting wire part comprised by the first signal line to which the cross-line part belongs; and
wherein the cross-line part is electrically connected, through a fourth via hole, to the signal connecting wire part comprised by the first signal line to which the cross-line part belongs.

11. The display panel according to claim 3, further comprising a fourth conductive layer arranged on a side of the third conductive layer away from the base;
wherein the first signal line further comprises a signal body line part;
wherein the signal body line part comprises a first body line portion, a second body line portion, and a third body line portion; the first body line portion, the second body line portion, and the third body line portion are located in different conductive layers;
wherein an orthographic projection of the third body line portion onto the base at least partially overlaps with an orthographic projection of the first body line portion onto the base, and the orthographic projection of the third body line portion onto the base at least partially overlaps with an orthographic projection of the second body line portion onto the base; and
wherein the third body line portion is electrically connected to the second body line portion through a fifth via hole, and the third body line portion is electrically connected to the first body line portion through a sixth via hole.

12. The display panel according to claim 11, wherein the fourth conductive layer comprises a pixel electrode provided in the display region.

13. The display panel according to claim 11, wherein the first signal line further comprises a first transition part; an orthographic projection of the first transition part onto the base at least partially overlaps with an orthographic projection, onto the base, of the signal connecting wire part comprised by the first signal line to which the cross-line part belongs;
the orthographic projection of the first transition part onto the base at least partially overlaps with the orthographic projection of the cross-line part onto the base;
wherein the first transition part is electrically connected to the signal connecting wire part through a seventh via hole, and the first transition part is electrically connected to the cross-line part through an eighth via hole; and
wherein the first transition part and the signal connecting wire are located in different layers, and the first transition part and the cross-line part are located in different conductive layers.

14. The display panel according to claim 1, comprising a second conductive layer, a third conductive layer, a fifth conductive layer, a sixth conductive layer, and a fourth conductive layer that are sequentially arranged in a direction away from the base; the fifth conductive layer is overlapped and connected with the sixth conductive layer; at least one insulating layer is provided between the second conductive layer and the third conductive layer, at least one insulating layer is provided between the third conductive layer and the fifth conductive layer, and at least one insulating layer is provided between the sixth conductive layer and the fourth conductive layer; and
wherein at least a portion of the cross-line part is located in the sixth conductive layer, and the signal connecting wire part is located in the second conductive layer.

15. The display panel according to claim 14, wherein the second conductive layer comprises a gate line provided in the display region, the third conductive layer comprises a data line provided in the display region, the fifth conductive layer comprises a common electrode provided in the display region, and the sixth conductive layer comprises an auxiliary metal pattern provided in the display region.

16. The display panel according to claim 14, wherein the first signal line further comprises a first transition part;
wherein the first transition part is electrically connected to the signal connecting wire part through a ninth via hole, and the first transition part is electrically connected to the cross-line part through a tenth via hole; and
wherein the first transition part and the signal connecting wire part are located in different layers, and the first transition part and the cross-line part are located in different conductive layers.

17. The display panel according to claim 14, wherein the first signal line further comprises a first transition part and a second transition part; the second transition part is overlapped and connected with the cross-line part;
wherein the first transition part is electrically connected to the signal connecting wire part through a thirteenth via hole, and the first transition part is electrically connected to the second transition part through a fourteenth via hole; and
wherein the first transition part and the signal connecting wire part are located in different layers, and the first transition part and the second transition part are located in different conductive layers;
or,
wherein the first signal line further comprises a third transition part and a connecting wire; wherein the third transition part is electrically connected to the cross-line part through an eleventh via hole, and the third transition part is electrically connected to the connecting wire through a twelfth via hole; and wherein the third transition part and the cross-line part are located in different conductive layers, and the third transition part and the connecting wire are located in different conductive layers;
or,
wherein the first signal line further comprises a first connecting part located in the fifth conductive layer; the first connecting part is overlapped and connected with the cross-line part; wherein an orthographic projection of the first connecting part onto the base covers an orthographic projection of a cross-line region onto the base; and wherein the cross-line region is an overlap region between the cross-line part and the signal connecting wire part comprised by at least a portion of the plurality of second sub-signal lines.

18-19. (canceled)

20. The display panel of claim 14, wherein the cross-line part comprises a first cross-line portion and a second cross-line portion;
wherein an orthographic projection of the first cross-line portion onto the base covers an orthographic projection of the second cross-line portion onto the base; and
wherein the first cross-line portion is directly overlapped and connected with the second cross-line portion.

21. The display panel according to claim 20, wherein the first signal line further comprises a first transition part and a second transition part; the second transition part is electrically connected to the first cross-line portion;
wherein the first transition part is electrically connected to a clock signal connecting wire part through a thirteenth via hole, and the first transition part is electrically connected to the second transition part through a fourteenth via hole; and
wherein the first transition part and the signal connecting wire part are located in different conductive layers, and the first transition part and the second transition part are located in different conductive layers;
or,
wherein the first signal line further comprises a third transition part, a fourth transition part, and a connecting wire; wherein the fourth transition part is electrically connected to the first cross-line portion; the fourth transition part and the first cross-line portion are located in a same conductive layer; wherein the third transition part is electrically connected to the fourth transition part through a fifteenth via hole, and the third transition part is electrically connected to the connecting wire through a sixteenth via hole; and wherein the third transition part and the fourth transition part are located in different conductive layers, and the third transition part and the connecting wire are located in different conductive layers.

22. (canceled)

23. A display device, comprising the display panel according to claim 1.
